(19) United States
(12) Patent Application Publication
(10) Pub. No.: US 2025/0380603 A1
(43) Pub. Date: Dec. 11, 2025

(54) DISPLAY DEVICE, WEARABLE ELECTRONIC DEVICE, AND METHOD OF MANUFACTURING DISPLAY DEVICE

(71) Applicant: Samsung Display Co., LTD., Yongin-si (KR)

(72) Inventors: Seok Hyun LIM, Yongin-si (KR); Tae Seop KIM, Yongin-si (KR); Eun Ho SONG, Yongin-si (KR); Da Sol JEONG, Yongin-si (KR); Seung Hwan CHO, Yongin-si (KR)

(21) Appl. No.: 19/079,305

(22) Filed: Mar. 13, 2025

(30) Foreign Application Priority Data
Jun. 5, 2024 (KR) 10-2024-0073515

(51) Int. Cl. H10K 59/88; G02B 27/01; H10K 59/12; H10K 59/122; H10K 59/35; H10K 102/00

(52) U.S. Cl. CPC H10K 59/88; G02B 27/0172; H10K 59/1201; H10K 59/122; H10K 59/353; H10K 2102/311

(57) ABSTRACT

One or more embodiments provides a display device including a substrate, sub-pixels respectively including a light-emitting area above the substrate, a planarization layer above the substrate, a pixel-defining layer above the planarization layer, a trench defined by a recessed portion of the pixel-defining layer in a non-light-emitting area surrounding the light-emitting area, and including a horizontal portion extending in a first direction, and a vertical portion extending in a second direction crossing the first direction, and a dummy pattern between adjacent ones of the sub-pixels in a crossing portion where the horizontal portion and the vertical portion cross.

### CROSS-REFERENCE TO RELATED APPLICATION

The present application claims priority to, and the benefit of, Korean Patent Application No. 10-2024-0073515, filed on Jun. 5, 2024, in the Korean Intellectual Property Office, the entire disclosure of which is incorporated herein by reference.

### BACKGROUND

### 1. Field

The present disclosure relates to a display device, a wearable electronic device, and a method of manufacturing the display device.

### 2. Description of the Related Art

Recently, as interest in an information display is increasing, research and development for display devices are continuously conducted.

### SUMMARY

The present disclosure may provide a display device with improved reliability, a wearable electronic device, and a method of manufacturing the display device.

One or more embodiments provides a display device including a substrate, sub-pixels respectively including a light-emitting area above the substrate, a planarization layer above the substrate, a pixel-defining layer above the planarization layer, a trench defined by a recessed portion of the pixel-defining layer in a non-light-emitting area surrounding the light-emitting area, and including a horizontal portion extending in a first direction, and a vertical portion extending in a second direction crossing the first direction, and a dummy pattern between adjacent ones of the sub-pixels in a crossing portion where the horizontal portion and the vertical portion cross.

The dummy pattern may include a first dummy pattern, and a second dummy pattern above the first dummy pattern.

The first dummy pattern may include a same material as the planarization layer, and the second dummy pattern may include a same material as the pixel-defining layer.

The pixel-defining layer may include a first inorganic insulating layer, a second inorganic insulating layer, and a third inorganic insulating layer sequentially stacked, wherein the second dummy pattern includes a first sub-pattern including a same material as, and at a same layer as, the first inorganic insulating layer, a second sub-pattern including a same material as, and at a same layer as, the second inorganic insulating layer, and a third sub-pattern including a same material as, and at a same layer as, the third inorganic insulating layer, the first, second, and third sub-patterns being sequentially stacked.

The horizontal portion may have a first width in the second direction, wherein the vertical portion has a second width in the first direction that is substantially equal to the second width.

A shortest distance between the dummy pattern and a sidewall of the pixel-defining layer in a diagonal direction of the first and second directions in the crossing portion may be substantially equal to the first width and the second width.

The dummy pattern may have one of a quadrangular shape, a polygonal shape, or a circular shape in plan view.

The dummy pattern may be above the planarization layer, and may include a same material as the pixel-defining layer.

The display device may further include an anode electrode of the sub-pixels above the planarization layer, a light-emitting structure above the anode electrode in the light-emitting area, and above the pixel-defining layer and the dummy pattern in the non-light-emitting area, and a cathode electrode above the light-emitting structure.

The light-emitting structure may include a first light-emitting portion above the anode electrode and the pixel-defining layer, configured to emit light, and disconnected at the trench, an intermediate layer above the first light-emitting portion, and disconnected at the trench, and a second light-emitting portion above the intermediate layer, configured to emit light, and not disconnected at the trench.

The first light-emitting portion above the dummy pattern and the first light-emitting portion above the pixel-defining layer may be spaced apart from each other, wherein the intermediate layer above the dummy pattern and the intermediate layer above the pixel-defining layer are spaced apart from each other, and wherein the second light-emitting portion above the dummy pattern and the second light-emitting portion above the pixel-defining layer are connected.

The crossing portion of the trench may include a first void and a second void surrounded by the first light-emitting portion, the intermediate layer, the second light-emitting portion, and the dummy pattern.

The light-emitting structure may include a first light-emitting portion above the anode electrode and the pixel-defining layer, and configured to emit light, a first intermediate layer above the first light-emitting portion, a second light-emitting portion above the first intermediate layer, and configured to emit light, a second intermediate layer above the second light-emitting portion, and a third light-emitting portion above the second intermediate layer, and configured to emit light, and wherein the first light-emitting portion, the first intermediate layer, the second light-emitting portion, and the second intermediate layer are disconnected at the trench, and the third light-emitting portion is not disconnected at the trench.

The first light-emitting portion above the dummy pattern and the first light-emitting portion above the pixel-defining layer may be spaced apart from each other, wherein the first intermediate layer above the dummy pattern and the first intermediate layer above the pixel-defining layer are spaced apart from each other, wherein the second light-emitting portion above the dummy pattern and the second light-emitting portion above the pixel-defining layer are spaced apart from each other, wherein the second intermediate layer above the dummy pattern and the second intermediate layer above the pixel-defining layer are spaced apart from each other, and wherein the third light-emitting portion above the dummy pattern and the third light-emitting portion above the pixel-defining layer of the sub-pixels are connected.

The crossing portion of the trench may include a first void and a second void that are surrounded by the first light-emitting portion, the first intermediate layer, the second light-emitting portion, the second intermediate layer, the third light-emitting portion, and the dummy pattern.

The sub-pixels may include a first sub-pixel configured to emit light of a first color, a second sub-pixel configured to emit light of a second color, and a third sub-pixel configured to emit light of a third color, wherein the light-emitting area includes a first light-emitting area forming the first sub-pixel, a second light-emitting area forming the second sub-pixel, and a third light-emitting area forming the third sub-pixel, and wherein the trench surrounds the first light-emitting area, the second light-emitting area, and the third light-emitting area in plan view.

One or more other embodiments provide a wearable electronic device including a lens, a display panel below the lens, and including a substrate sub-pixels respectively including a light-emitting area above the substrate, a planarization layer above the substrate, a pixel-defining layer above the planarization layer, a trench defined by a recessed portion of the pixel-defining layer in a non-light-emitting area surrounding the light-emitting area, and including a horizontal portion extending in a first direction, and a vertical portion extending in a second direction crossing the first direction, and a dummy pattern between adjacent sub-pixels in the non-light-emitting area in a crossing portion where the horizontal portion and the vertical portion cross.

The dummy pattern may include a same material as the pixel-defining layer.

One or more other embodiments provide a method of manufacturing a display device provided with sub-pixels including a light-emitting area, the method including forming a planarization layer above a pixel circuit layer above a substrate, forming an anode electrode above the planarization layer, forming a pixel-defining layer above the planarization layer and the anode electrode, arranging a mask above an upper portion of the pixel-defining layer, performing a photolithography process to form a trench including a horizontal portion extending in a first direction, and a vertical portion extending in a second direction crossing the first direction, and a dummy pattern in a crossing portion where the horizontal portion and the vertical portion cross, by recessing at least a portion of the pixel-defining layer in a non-light-emitting area surrounding the light-emitting area, forming a light-emitting structure above the pixel-defining layer, the trench, and the dummy pattern, and forming a cathode electrode above the light-emitting structure.

The dummy pattern may include a same material as the pixel-defining layer.

According to the display device and the wearable electronic device of the embodiments, reliability may be improved by easily controlling voids and dimensions (e.g., CD or critical dimensions, although the dimensions are not necessarily “critical” according to the dictionary meaning of the word) at the crossing portion (e.g., intersection portion), by arranging the dummy pattern (or structure) at the crossing portion where the horizontal and vertical portions of the trench cross or intersect to allow the width between the sidewalls of the pixel-defining layer at the horizontal portion (and vertical portion) and the width (or the shortest distance) between the pixel-defining layer and the dummy pattern at the crossing portion to be similar.

Aspects of embodiments of the present disclosure are not limited by what is illustrated in the above, and more various aspects are included in the present specification.

### BRIEF DESCRIPTION OF THE DRAWINGS

FIG. 1 illustrates a schematic block diagram of a display device according to one or more embodiments.

FIG. 2 illustrates a schematic block diagram of one of sub-pixels of FIG. 1 according to one or more embodiments.

FIG. 3 illustrates a schematic circuit diagram of the sub-pixel of FIG. 2 according to one or more embodiments.

FIG. 4 illustrates a schematic top plan view of a display device of FIG. 1 according to one or more embodiments.

FIG. 5 illustrates a schematic exploded perspective view of a portion of a display panel of FIG. 4.

FIG. 6A illustrates a schematic top plan view of one of pixels of FIG. 5 according to one or more embodiments.

FIG. 6B illustrates a schematic top plan view of one of pixels of FIG. 5 according to one or more other embodiments.

FIG. 6C illustrates a schematic top plan view of one of pixels of FIG. 5 according to one or more other embodiments.

FIG. 7 illustrates a schematic cross-sectional view of one or more embodiments of a pixel taken along the line I-I′ of FIG. 6A.

FIG. 8 illustrates a schematic cross-sectional view of a light-emitting structure included in one of first to third light-emitting elements of FIG. 7 according to one or more embodiments.

FIG. 9 illustrates a schematic cross-sectional view of a light-emitting structure included in one of first to third light-emitting elements of FIG. 7 according to one or more other embodiments.

FIG. 10 illustrates a schematic top plan view of one portion of a display area of FIG. 4.

FIG. 11A and FIG. 11B illustrate schematic enlarged top plan views of area A1 of FIG. 10.

FIG. 12A and FIG. 12B illustrate a schematic cross-sectional view taken along the line II-II′ of FIG. 10.

FIG. 13 illustrates a schematic cross-sectional view taken along the line III-III′ of FIG. 10.

FIG. 14 and FIG. 15 illustrate enlarged views of a portion of the display device of FIG. 7, and illustrate cross-sectional views taken along the line II-II′ of FIG. 10.

FIG. 16 illustrates a schematic flowchart of a manufacturing method of a display device according to one or more embodiments.

FIG. 17A to FIG. 17F illustrate schematic cross-sectional views of a manufacturing method of a display device according to one or more embodiments.

FIG. 18 and FIG. 19 illustrate schematic top plan views of one portion of a display area of a display device according to one or more embodiments.

FIG. 20 illustrates a schematic block diagram of a display system according to one or more embodiments.

FIG. 21 illustrates a schematic perspective view of an application example of the display system of FIG. 20.

FIG. 22 schematically illustrates a user wearing a head-mounted display device of FIG. 21.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively. In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value. Further, the use of “may” when describing embodiments of the present disclosure refers to “one or more embodiments of the present disclosure.”

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

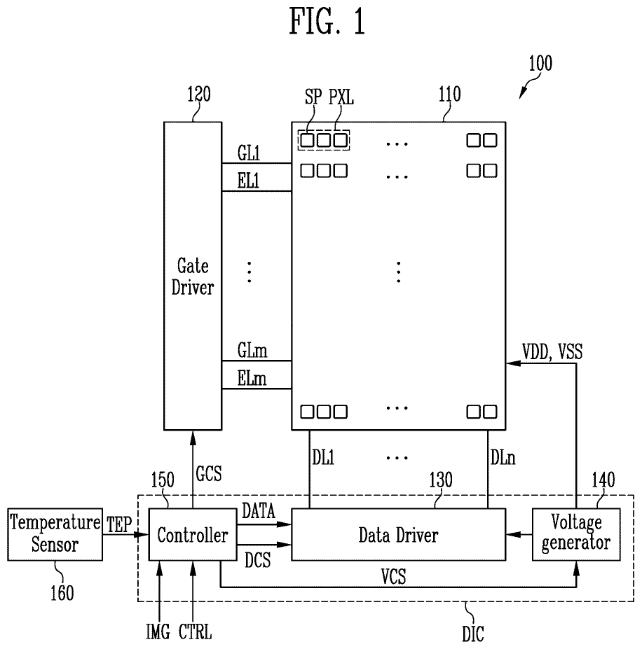

FIG. 1 illustrates a schematic block diagram of a display device 100 according to one or more embodiments.

Referring to FIG. 1, the display device 100 may include a display panel 110 (or a display portion), a gate driver 120, a data driver 130, a voltage generator 140, and a controller 150.

The display panel 110 may include sub-pixels SP. The sub-pixels SP may be connected to the gate driver 120 through first to m-th gate lines GL1 to GLm. The sub-pixels SP may be connected to the data driver 130 through first to n-th data lines DL1 to DLn.

Each of the sub-pixels SP may include at least one light-emitting element configured to generate light. Accordingly, the sub-pixels SP may respectively generate light of a corresponding color, such as red, green, blue, cyan, magenta, yellow, or the like. Two or more of the sub-pixels SP may configure one pixel PXL. For example, as shown in FIG. 1, three sub-pixels may configure one pixel PXL.

The gate driver 120 may be connected to the sub-pixels SP arranged in a row direction through the first to m-th gate lines GL1 to GLm. The gate driver 120 may output gate signals to the first to m-th gate lines GL1 to GLm in response to a gate control signal GCS. In embodiments, the gate control signal GCS may include a start signal indicating the start of each frame, a horizontal synchronization signal for outputting gate signals in synchronization with the timing at which data signals are applied, and the like.

In some embodiments, first to m-th light-emitting control lines EL1 to ELm connected to the sub-pixels SP in a row direction may be further provided. In this case, the gate driver 120 may include a light-emitting control driver configured to control the first to m-th light-emitting control lines EL1 to ELm. The light-emitting control driver may operate under the control of the controller 150.

The gate driver 120 may be located on one side of the display panel 110. However, embodiments are not limited thereto. For example, the gate driver 120 may be divided into two or more physically and/or logically separated drivers, and the drivers may be located on one side of the display panel 110 and on the other side of the display panel 110 opposite to the one side. As described above, the gate driver 120 may be located around the display panel 110 in various forms according to the embodiments.

The data driver 130 may be connected to the sub-pixels SP arranged in a column direction through the first to n-th data lines DL1 to DLn. The data driver 130 may receive image data (DATA) and a data control signal DCS from the controller 150. The data driver 130 may operate in response to the data control signal DCS. In embodiments, the data control signal DCS may include a source start pulse, a source shift clock, a source output enable signal, and the like.

The data driver 130 may use voltages from the voltage generator 140 to apply data signals having grayscale voltages corresponding to the image data DATA to the first to n-th data lines DL1 to DLn. In case that a gate signal is applied to each of the first to m-th gate lines GL1 to GLm, data signals corresponding to the image data DATA may be applied to the data lines DL1 to DLm. Accordingly, the corresponding sub-pixels SP may generate light corresponding to the data signals. Accordingly, an image may be displayed on the display panel 110.

In some embodiments, the gate driver 120 and the data driver 130 may include complementary metal-oxide semiconductor (CMOS) circuit elements.

The voltage generator 140 may operate in response to a voltage control signal VCS from the controller 150. The voltage generator 140 may be configured to generate a plurality of voltages, and to provide the generated voltages to constituent elements of the display device 100. For example, the voltage generator 140 may be configured to generate a plurality of voltages by receiving an input voltage from the outside of the display device 100, by adjusting the received voltage, and by regulating the adjusted voltage.

The voltage generator 140 may generate a first power voltage VDD and a second power voltage VSS, and the generated first and second power voltages VDD and VSS may be provided to the sub-pixels SP. The first power voltage VDD may have a relatively high voltage level, and the second power voltage VSS may have a voltage level lower than the first power voltage VDD. In other embodiments, the first power voltage VDD or the second power voltage VSS may be provided by an external device of the display device 100.

In addition, the voltage generator 140 may generate various voltages. For example, the voltage generator 140 may generate an initialization voltage applied to the sub-pixels SP. For example, during a sensing operation to sense electrical characteristics of transistors and/or light-emitting elements of the sub-pixels SP, a reference voltage (e.g., predetermined reference voltage) may be applied to the first to n-th data lines DL1 to DLn, and the voltage generator 140 may generate the reference voltage.

The controller 150 may control various operations of the display device 100. The controller 150 may receive input image data IMG and a control signal CTRL for controlling the display of the input image data (e.g., which may be externally supplied). The controller 150 may provide the gate control signal GCS, the data control signal DCS, and the voltage control signal VCS in response to the control signal CTRL.

The controller 150 may convert the input image data IMG to be suitable for the display device 100 or the display panel 110 to output the image data DATA. In embodiments, the controller 150 may output the image data DATA by aligning the input image data IMG to be suitable for the sub-pixels SP of a row unit.

Two or more components of the data driver 130, the voltage generator 140, and the controller 150 may be mounted on one integrated circuit. As shown in FIG. 1, the data driver 130, the voltage generator 140, and the controller 150 may be included in a driver integrated circuit DIC. In this case, the data driver 130, the voltage generator 140, and the controller 150 may be functionally separate components within one driver integrated circuit DIC. In other embodiments, at least one of the data driver 130, the voltage generator 140, or the controller 150 may be provided as a component separated from the driver integrated circuit DIC.

The display device 100 may include at least one temperature sensor 160. The temperature sensor 160 may be configured to sense a surrounding temperature, and to generate temperature data TEP representing the sensed temperature. In embodiments, the temperature sensor 160 may be adjacent to the display panel 110 and/or the driver integrated circuit DIC.

The controller 150 may control various operations of the display device 100 in response to the temperature data TEP. In embodiments, the controller 150 may adjust the luminance of an image outputted from the display panel 110 in response to the temperature data TEP. For example, the controller 150 may control the data signals and the first and second power voltages VDD and VSS by controlling components, such as the data driver 130 and/or the voltage generator 140.

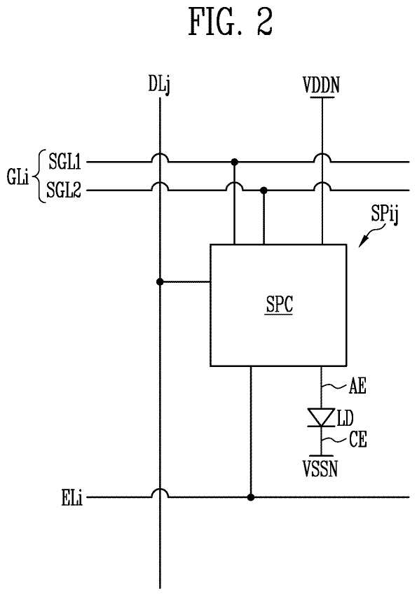

FIG. 2 illustrates a schematic block diagram of one of sub-pixels of FIG. 1 according to one or more embodiments. In FIG. 2, among the sub-pixels SP of FIG. 1, a sub-pixel SPij located in an i-th row (i is an integer greater than or equal to 1 and less than or equal to m) and a j-th column (j is an integer greater than or equal to 1 and less than or equal to n) is illustrated as an example.

Referring to FIG. 2, the sub-pixel SPij may include a sub-pixel circuit SPC and a light-emitting element LD.

The light-emitting element LD may be connected between a first power voltage node VDDN and a second power voltage node VSSN. In this case, the first power voltage node VDDN may be a node that transmits the first power voltage VDD of FIG. 1, and the second power voltage node VSSN may be a node that transmits the second power voltage VSS of FIG. 1.

An anode electrode AE of the light-emitting element LD may be connected to the first power voltage node VDDN through the sub-pixel circuit SPC, and a cathode electrode CE of the light-emitting element LD may be connected to the second power voltage node VSSN. For example, the anode electrode AE of the light-emitting element LD may be connected to the first power voltage node VDDN through one or more transistors included in the sub-pixel circuit SPC.

The sub-pixel circuit SPC may be connected to an i-th gate line GLi among the first to m-th gate lines GL1 to GLm of FIG. 1, an i-th light-emitting control line ELi among the first to m-th light-emitting control lines EL1 to ELm of FIG. 1, and a j-th data line DLj among the first to n-th data lines DL1 to DLm of FIG. 1. The sub-pixel circuit SPC may be configured to control the light-emitting element LD according to signals received through these signal lines.

The sub-pixel circuit SPC may operate in response to a gate signal received through the i-th gate line GLi. The i-th gate line GLi may include one or more sub-gate lines. In embodiments, as shown in FIG. 2, in case that the i-th gate line GLi includes two or more sub-gate lines, the sub-pixel circuit SPC may operate in response to gate signals received through the corresponding sub-gate lines.

The sub-pixel circuit SPC may operate in response to a light-emitting control signal received through the i-th light-emitting control line ELi. In the embodiments, the i-th light-emitting control line ELi may include one or more sub-light-emitting control lines. In case that the i-th light-emitting control line ELi includes two or more sub-light-emitting control lines, the sub-pixel circuit SPC may operate in response to light-emitting control signals received through the corresponding sub-light-emitting control lines.

The sub-pixel circuit SPC may receive a data signal through the j-th data line DLj. The sub-pixel circuit SPC may store a voltage corresponding to the data signal in response to at least one of the gate signals received through the first and second sub-gate lines SGL1 and SGL2. In response to the light-emitting control signal received through the i-th light-emitting control line ELi, the sub-pixel circuit SPC may adjust the current flowing from the first power voltage node VDDN to the second power voltage node VSSN through the light-emitting element LD according to the stored voltage. Accordingly, the light-emitting element LD may generate light of luminance corresponding to the data signal.

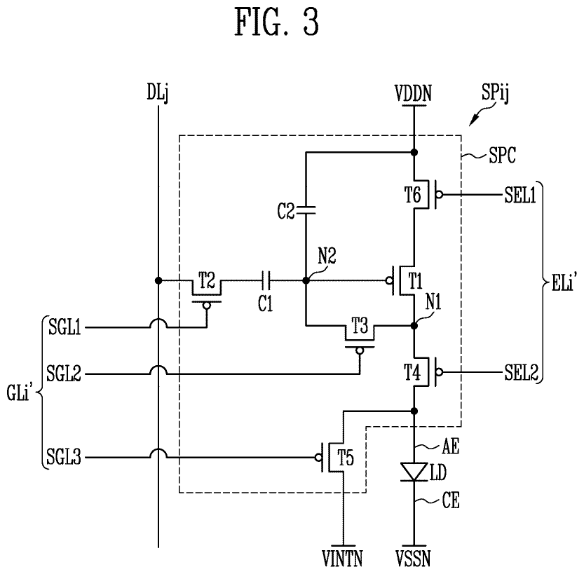

FIG. 3 illustrates a schematic circuit diagram of the sub-pixel SPij of FIG. 2 according to one or more embodiments.

Referring to FIG. 3, the sub-pixel SPij may include a sub-pixel circuit SPC and a light-emitting element LD.

The sub-pixel circuit SPC may be connected to an i-th gate line GLi′, an i-th light-emitting control line ELi′, and a j-th data line DLj. Compared to the i-th gate line GLi of FIG. 2, the i-th gate line GLi′ may further include a third sub-gate line SGL3. Compared to the i-th light-emitting control line ELi of FIG. 2, the i-th light-emitting control line ELi′ may include a first sub-light-emitting control line SEL1 and a second sub-light-emitting control line SEL2.

The sub-pixel circuit SPC may include the first to sixth transistors T1 to T6 and the first and second capacitors C1 and C2.

The first transistor T1 may be connected between the first power voltage node VDDN and a first node N1. A gate of the first transistor T1 is connected to a second node N2, and accordingly, the first transistor T1 may be turned on according to a voltage level of the second node N2. The first transistor T1 may be referred to as a driving transistor.

The second transistor T2 may be connected between the j-th data line DLj and the second node N2. A gate of the second transistor T2 is connected to the first sub-gate line SGL1, and accordingly, the second transistor T2 may be turned on in response to the gate signal of the first sub-gate line SGL1. The second transistor T2 may be referred to as a switching transistor.

The third transistor T3 may be connected between the first node N1 and the second node N2. A gate of the third transistor T3 is connected to the second sub-gate line SGL2, and accordingly, the third transistor T3 may be turned on in response to the gate signal of the second sub-gate line SGL2.

The fourth transistor T4 may be connected between the first node N1 and the anode electrode AE of the light-emitting element LD. A gate of the fourth transistor T4 is connected to the second sub-light-emitting control line SEL2, and accordingly, the fourth transistor T4 may be turned on in response to the light-emitting control signal of the second sub-light-emitting control line SEL2.

The fifth transistor T5 may be connected between the anode electrode AE of the light-emitting element LD and an initialization voltage node VINTN. The initialization voltage node VINTN may be configured to transmit an initialization voltage. In embodiments, the initialization voltage may be provided by the voltage generator 140 of FIG. 1. In other embodiments, the initialization voltage may be provided by an external device to the display device 100. A gate of the fifth transistor T5 is connected to the third sub-gate line SGL3, and accordingly, the fifth transistor T5 may be turned on in response to the gate signal of the third sub-gate line SGL3.

The sixth transistor T6 may be connected between a first power voltage node VDDN and the first transistor T1. A gate of the sixth transistor T6 is connected to the first sub-light-emitting control line SEL1, and accordingly, the sixth transistor T6 may be turned on in response to the light-emitting control signal of the first sub-light-emitting control line SEL1.

The first capacitor C1 may be connected between the second transistor T2 and the second node N2. The second capacitor C2 may be connected between the first power voltage node VDDN and the second node N2.

As described above, the sub-pixel circuit SPC may include the first to sixth transistors T1 to T6 and the first and second capacitors C1 and C2. However, embodiments are not limited thereto. The sub-pixel circuit SPC may be implemented as one of various circuits including a plurality of transistors and/or one or more capacitors. For example, the sub-pixel circuit SPC may include two transistors and one capacitor. According to the embodiments of the sub-pixel circuit SPC, the number of sub-gate lines included in the i-th gate line GLi′ and the number of sub-light-emitting control lines included in the i-th light-emitting control line ELi′ may vary.

The first to sixth transistors T1 to T6 may be P-type transistors. Each of the first to sixth transistors T1 to T6 may be a metal oxide silicon field effect transistor (MOSFET). However, embodiments are not limited thereto. For example, at least one of the first to sixth transistors T1 to T6 may be replaced with an N-type transistor.

In embodiments, the first to sixth transistors T1 to T6 may include an amorphous silicon semiconductor, a monocrystalline silicon semiconductor, a polycrystalline silicon semiconductor, a metal oxide semiconductor, and the like.

The light-emitting element LD may include the anode electrode AE, the cathode electrode CE, and the light-emitting layer. The light-emitting layer may be located between the anode electrode AE and the cathode electrode CE. After the data signal transmitted through the j-th data line DLj is reflected in the voltage of the second node N2, the fourth and sixth transistors T4 and T6 may be turned on in case that the light-emitting control signals of the first and second sub-light-emitting control lines SEL1 and SEL2 are enabled to a low level. In addition, the first transistor T1 may be turned on according to the voltage of the second node N2, and accordingly, a current may flow from the first power voltage node VDDN to the second power voltage node VSSN. The light-emitting element LD may emit light depending on the amount of current flowing.

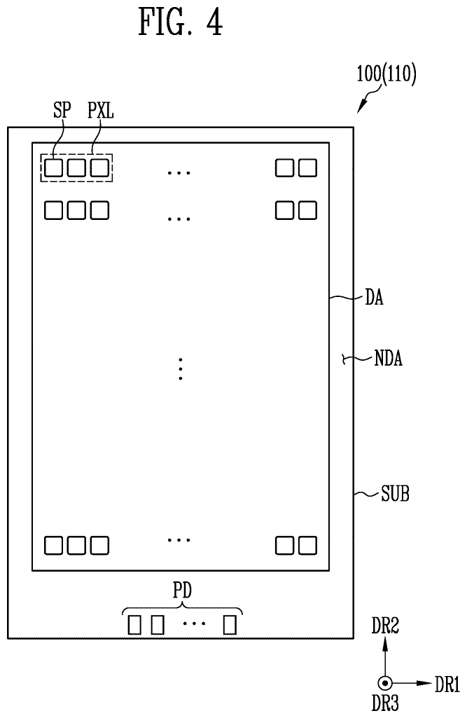

FIG. 4 illustrates a schematic top plan view of the display device 100 of FIG. according to one or more embodiments. For convenience, FIG. 4 briefly illustrates the structure of the display device 100, for example, the display panel 110 provided in the display device 100, based on a display area DA in which an image is displayed.

Referring to FIG. 4, the display panel 110 may include the display area DA and a non-display area NDA. The display panel 110 may display an image through the display area DA. The non-display area NDA may be located around the display area DA.

The display panel 110 may include a substrate SUB, sub-pixels SP, and pads PD.

In case that the display panel 110 is used as a display screen for a head-mounted display (HMD), a virtual reality (VR) device, a mixed reality (MR) device, or an augmented reality (AR) device, the display panel 110 may be positioned very close to the user's eyes. In this case, the sub-pixels SP with relatively high integration may be required. To increase the integration of the sub-pixels SP, the substrate SUB may be provided as a silicon substrate (or silicon wafer), but is not limited thereto. The sub-pixels SP and/or the display panel 110 may be formed on the substrate SUB, which is a silicon substrate. The display device 100 including the display panel 110 formed on the substrate SUB, which is a silicon substrate, may be referred to as an OLED on silicon (OLEDoS) display device.

The sub-pixels SP may be located in the display area DA on the substrate SUB. The sub-pixels SP may be arranged in a matrix form along a first direction DR1, and along a second direction DR2 crossing the first direction DR1, but the arrangement of the sub-pixels SP is not limited thereto. For example, the sub-pixels SP may be arranged in a zigzag form along first direction DR1 and second direction DR2. For example, the sub-pixels SP may be located in a PENTILE™ shape (PENTILE™ being a registered trademark of Samsung Display Co., Ltd., Republic of Korea). The first direction DR1 may be a row direction, and the second direction DR2 may be a column direction.

Two or more of the plurality of sub-pixels SP may configure one pixel PXL. A constituent element to control the sub-pixels SP may be located in the non-display area NDA on the substrate SUB. For example, wires connected to the sub-pixels SP, such as the first to m-th gate lines GL1 to GLm and the first to n-th data lines DL1 to DLn of FIG. 1, may be located in the non-display area NDA.

At least one of the gate driver 120, the data driver 130, the voltage generator 140, the controller 150, or the temperature sensor 160 in FIG. 1 may be integrated in the non-display area NDA of the display panel 110. In embodiments, the gate driver 120 of FIG. 1 may be mounted on the display panel 110, and may be located in the non-display area NDA. In other embodiments, the gate driver 120 may be implemented as an integrated circuit separated from the display panel 110. In embodiments, the temperature sensor 160 may be located in the non-display area NDA to detect the temperature of the display panel 110.

The pads PD may be located in the non-display area NDA on the substrate SUB. The pads PD may be electrically connected to the sub-pixels SP through wires. For example, the pads PD may be connected to the sub-pixels SP through the first to n-th data lines DL1 to DLn.

The pads PD may interface the display panel 110 to other constituent elements of the display device 100. In embodiments, voltages and signals required for operations of constituent elements included in the display panel 110 may be provided from the driver integrated circuit DIC of FIG. 1 through the pads PD. For example, the first to n-th data lines DL1 to DLn may be connected to the driver integrated circuit DIC through the pads PD. For example, the first and second power voltages VDD and VSS may be received from the driver integrated circuit DIC through the pads PD. For example, in case that the gate driver 120 is mounted on the display panel 110, the gate control signal GCS may be transmitted from the driver integrated circuit DIC to the gate driver 120 through the pads PD.

In embodiments, the circuit board may be electrically connected to the pads PD by using a conductive adhesive member, such as an anisotropic conductive film. In this case, the circuit board may be a flexible printed circuit board (FPCB) or a flexible film made of a flexible material. The driver integrated circuit DIC may be mounted on the circuit board to be electrically connected to the pads PD.

In embodiments, the display area DA may have various shapes. The display area DA may have a closed-loop shape including sides of a straight line and/or a curved line. For example, the display area DA may have shapes, such as a polygonal shape, a circular shape, a semicircular, and an elliptical shape.

In embodiments, the display panel 110 may have a flat display surface. In other embodiments, the display panel 110 may have a display surface that is at least partially round. In embodiments, the display panel 110 may be bendable, foldable, or rollable. In these cases, the display panel 110 and/or the substrate SUB may include materials with flexible properties.

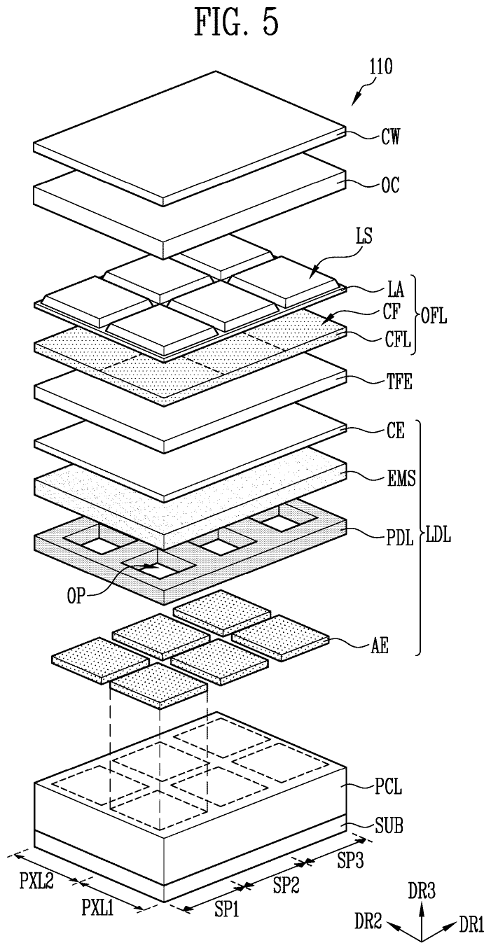

FIG. 5 illustrates a schematic exploded perspective view of a portion of the display panel 110 of FIG. 4. In FIG. 5, for clear and concise description, a portion of the display panel 110 corresponding to two pixels PXL1 and PXL2 among the pixels PXL of FIG. 4 is schematically shown. Portions of the display panel 110 corresponding to the remaining pixels may be similarly configured.

Referring to FIG. 4 and FIG. 5, each of the first and second pixels PXL1 and PXL2 may include first to third sub-pixels SP1 to SP3. However, embodiments are not limited thereto. For example, each of the first and second pixels PXL1 and PXL2 may include four sub-pixels, or two sub-pixels.

In FIG. 5, the first to third sub-pixels SP1 to SP3 is illustrated to have quadrangular shapes, and to have the same sizes when viewed in a third direction DR3 crossing the first and second directions DR1 and DR2. However, embodiments are not limited thereto. In some embodiments, the first sub-pixel SP1, the second sub-pixel SP2, and the third sub-pixel SP3 may be modified to have various shapes.

The display panel 110 may include a substrate SUB, a pixel circuit layer PCL, a light-emitting element layer LDL, an encapsulation layer TFE, an optical functional layer OFL, an overcoat layer OC, and a cover window CW.

In embodiments, the substrate SUB may include a silicon wafer substrate formed using a semiconductor process. The substrate SUB may include a semiconductor material suitable for forming circuit elements. For example, the semiconductor material may include silicon, germanium, and/or silicon-germanium. The substrate SUB may be provided from a bulk wafer, an epitaxial layer, an epitaxial layer, a silicon on Insulator (SOI) layer, or a semiconductor on insulator (SeOI) layer. In other embodiments, the substrate SUB may include a glass substrate. In still other embodiments, the substrate SUB may include a polyimide (PI) substrate.

The pixel circuit layer PCL may be located on the substrate SUB (as used herein, “located on” may mean “above”). The substrate SUB and/or the pixel circuit layer PCL may include insulating layers and conductive patterns located between the insulating layers. The conductive patterns of the pixel circuit layer PCL may function as at least some of circuit elements, wires, and the like. The conductive patterns may include copper, but embodiments are not limited thereto.

The circuit elements may include the sub-pixel circuit (see “SPC” in FIG. 2) of each of the first to third sub-pixels SP1 to SP3. The sub-pixel circuit SPC may include transistors and one or more capacitors. Each transistor may include a semiconductor portion including a source region, a drain region, and a channel region, and a gate electrode overlapping the semiconductor portion. In embodiments, in case that the substrate SUB is provided as a silicon substrate, the semiconductor portion may be included in the substrate SUB, and the gate electrode may be included in the pixel circuit layer PCL as the conductive pattern of the pixel circuit layer PCL. In embodiments, in case that the substrate SUB is provided as a glass substrate or a PI substrate, the semiconductor portion and the gate electrode may be included in the pixel circuit layer PCL. Each capacitor may include electrodes spaced apart from each other. For example, each capacitor may include electrodes spaced apart from each other on a plane defined by the first and second directions DR1 and DR2. For example, each capacitor may include electrodes spaced apart from each other in the third direction DR3 with an insulating layer therebetween.

The wires of the pixel circuit layer PCL may include signal lines connected to each of the first to third sub-pixels SP1 to SP3, for example, a gate line, a light-emitting control line, and a data line. The wires may further include the wire connected to the first power voltage node VDDN of FIG. 2. In addition, the wires may further include the wire connected to the second power voltage node VSSN of FIG. 2.

The light-emitting element layer LDL may include anode electrodes AE, a pixel-defining layer PDL, a light-emitting structure EMS, and a cathode electrode CE.

The anode electrodes AE may be located on the pixel circuit layer PCL. The anode electrodes AE may contact circuit elements of the pixel circuit layer PCL. The anode electrodes AE may include an opaque conductive material capable of reflecting light, but embodiments are not limited thereto.

The pixel-defining layer PDL may be located on the anode electrodes AE. The pixel-defining layer PDL may include, or define, an opening OP exposing a portion of each of the anode electrodes AE. The opening OP of the pixel-defining layer PDL may be understood as light-emitting areas corresponding to the first to third sub-pixels SP1 to SP3, respectively.

In embodiments, the pixel-defining layer PDL may include an inorganic material. In this case, the pixel-defining layer PDL may include a plurality of stacked inorganic layers. For example, the pixel-defining layer PDL may include a silicon oxide (SiOₓ) and a silicon nitride (SiNₓ). In other embodiments, the pixel-defining layer PDL may include an organic material. However, the material of the pixel-defining layer PDL is not limited thereto.

The light-emitting structure EMS may be located on the anode electrodes AE exposed by the opening OP of the pixel-defining layer PDL. The light-emitting structure EMS may include a light-emitting layer configured to generate light, an electron transport layer configured to transport electrons, and a hole transport layer configured to transport holes.

In embodiments, the light-emitting structure EMS may fill the opening OP of the pixel-defining layer PDL, and may be located entirely on an upper portion of the pixel-defining layer PDL. In other words, the light-emitting structure EMS may extend across the first to third sub-pixels SP1 to SP3. In this case, at least some of the functional layers in the light-emitting structure EMS may be disconnected or bent at the boundaries between the first to third sub-pixels SP1 to SP3. However, embodiments are not limited thereto. For example, portions of the light-emitting structure EMS corresponding to the first to third sub-pixels SP1 to SP3 are separated from each other, and each of them may be located in the opening OP of the pixel-defining layer PDL.

The cathode electrode CE may be located on the light-emitting structure EMS. The cathode electrode CE may extend across the first to third sub-pixels SP1 to SP3. As such, the cathode electrode CE may be provided as a common electrode for the first to third sub-pixels SP1 to SP3.

The cathode electrode CE may be a thin metal layer with a thickness sufficient to transmit light emitted from the light-emitting structure EMS. The cathode electrode CE may be made of a metallic material or a transparent conductive material to have a relatively thin thickness. In embodiments, the cathode electrode CE may include at least one of various transparent conductive materials including an indium tin oxide, an indium zinc oxide, an indium tin zinc oxide, an aluminum zinc oxide, a gallium zinc oxide, a zinc tin oxide, or a gallium tin oxide. In other embodiments, the cathode electrode CE may include at least one of silver (Ag), magnesium (Mg), or a mixture thereof. However, the material of the cathode electrode CE is not limited thereto.

One of the anode electrodes AE, the portion of the light-emitting structure EMS overlapping it, and the portion of the cathode electrode CE overlapping it may be understood to configure one light-emitting element (see “LD” in FIG. 2). In other words, each of the light-emitting elements of the first to third sub-pixels SP1 to SP3 may include one anode electrode AE, a portion of the light-emitting structure EMS overlapping it, and a portion of the cathode electrode CE overlapping it. In each of the first to third sub-pixels SP1 to SP3, holes injected from the anode electrode AE and electrons injected from the cathode electrode CE are transported into the light-emitting layer of the light-emitting structure EMS to form excitons, and when the excitons transition from the excited state to the ground state, light may be generated. The luminance of light may be determined depending on the amount of current flowing through the light-emitting layer. Depending on the configuration of the light-emitting layer, the wavelength range of the generated light may be determined.

An encapsulation layer TFE may be located on the cathode electrode CE. The encapsulation layer TFE may cover the light-emitting element layer LDL and/or the pixel circuit layer PCL. The encapsulation layer TFE may be configured to reduce or prevent permeation of oxygen and/or moisture into the light-emitting element layer LDL. In embodiments, the encapsulation layer TFE may include a structure in which one or more inorganic layers and one or more organic layers are alternately stacked. For example, the inorganic layer may include a silicon nitride, a silicon oxide, or a silicon oxynitride (SiOₓN_{y}). The organic layer may include an organic insulating material, such as a polyacrylates resin, an epoxy resin, a phenolic resin, a polyamide resin, a polyimide resin, an unsaturated polyesters resin, a polyphenylenethers resin, a polyphenylenesulfides resin, or a benzocyclobutene (BCB). However, the materials of the organic layer and the inorganic layer of the encapsulation layer TFE are not limited thereto.

The encapsulation layer TFE may further include a thin film containing an aluminum oxide (AlOₓ) to improve the encapsulation efficiency of the encapsulation layer TFE. The thin film containing an aluminum oxide may be located on the upper surface of the encapsulation layer TFE facing the optical functional layer OFL, and/or the lower surface of the encapsulation layer TFE facing the light-emitting element layer LDL.

The thin film containing the aluminum oxide may be formed through atomic layer deposition (ALD). However, embodiments are not limited thereto. The encapsulation layer TFE may further include a thin film made of at least one of various materials suitable for improving the encapsulation efficiency.

The optical functional layer OFL may be located on the encapsulation layer TFE. The optical functional layer OFL may include a color filter layer CFL and a lens array LA.

The color filter layer CFL may be located between the encapsulation layer TFE and the lens array LA. The color filter layer CFL may be configured to selectively output light in a wavelength range or color corresponding to each sub-pixel by filtering light emitted from the light-emitting structure EMS. The color filter layer CFL includes color filters CF respectively corresponding to the first to third sub-pixels SP1 to SP3, and each of the color filters CF may pass light in a wavelength range corresponding to the sub-pixel. For example, a color filter corresponding to the first sub-pixel SP1 may pass red light, a color filter corresponding to the second sub-pixel SP2 may pass green light, and a color filter corresponding to the third sub-pixel SP3 may pass blue light. At least some of the color filters CF may be omitted according to light emitted from the light-emitting structure EMS of each sub-pixel.

The lens array LA may be located on the color filter layer CFL. The lens array LA may include lenses LS respectively corresponding to the first to third sub-pixels SP1 to SP3. Each of the lenses LS may improve light output efficiency by outputting light emitted from the light-emitting structure EMS in an intended path. The lens array LA may have a relatively high refractive index. For example, the lens array LA may have a higher refractive index than the overcoat layer OC. In embodiments, the lenses LS may include an organic material. In embodiments, the lenses LS may include an acrylate material. However, the material of the lenses LS is not limited thereto.

In embodiments, compared to the opening OP of the pixel-defining layer PDL, at least some of the color filters CF of the color filter layer CF and at least some of the lenses LS of the lens array LA may be shifted in a direction parallel to a plane defined by the first and second directions DR1 and DR2. For example, in the center area of the display area DA, the center of the color filter and the center of the lens may be aligned or overlapped with the center of the opening OP of the corresponding pixel-defining layer PDL when viewed in the third direction DR3. For example, in the central area of the display area DA, the opening OP of the pixel-defining layer PDL may completely overlap the corresponding color filter of the color filter layer CF and the corresponding lens of the lens array LA. In an area of the display area DA adjacent to the non-display area NDA, the center of the color filter and the center of the lens may be shifted in a planar direction from the center of the opening OP of the corresponding pixel-defining layer PDL when viewed in the third direction DR3. For example, in an area of the display area DA adjacent to the non-display area NDA, the opening OP of the pixel-defining layer PDL may partially overlap the corresponding color filter of the color filter layer CFL and the corresponding lens of the lens array LA. Accordingly, in the center of the display area DA, light emitted from the light-emitting structure EMS may be efficiently outputted in the normal direction of the display surface. Light emitted from the light-emitting structure EMS at the outside of the display area DA may be efficiently outputted in a direction inclined by an angle (e.g., predetermined angle) with respect to the normal direction of the display surface.

The overcoat layer OC may be located on the lens array LA. The overcoat layer OC may cover the optical functional layer OFL, the encapsulation layer TFE, the light-emitting structure EMS, and/or the pixel circuit layer PCL. The overcoat layer OC may include various materials suitable for protecting lower layers thereof from foreign substances, such as dust and moisture. For example, the overcoat layer OC may include at least one of an inorganic insulating layer or an organic insulating film. For example, the overcoat layer OC may include an epoxy resin, but embodiments are not limited thereto. The overcoat layer OC may have a lower refractive index than the lens array LA.

The cover window CW may be located on the overcoat layer OC. The cover window CW can be configured to protect lower layers thereof. The cover window CW may have a higher refractive index than the overcoat layer OC. The cover window CW may include glass, but embodiments are not limited thereto. For example, the cover window CW may be an encapsulation glass configured to protect constituent elements located thereunder. In other embodiments, the cover window CW may be omitted.

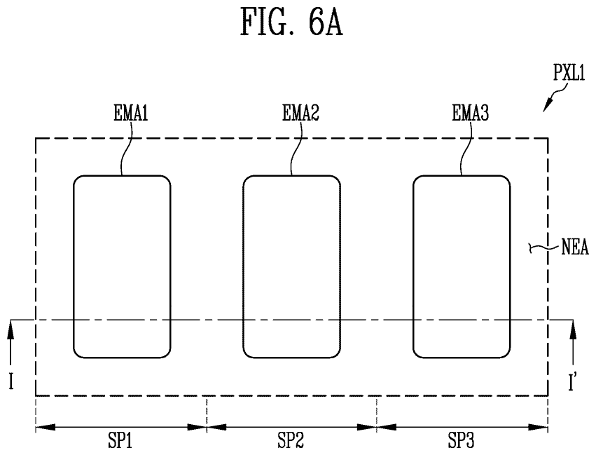

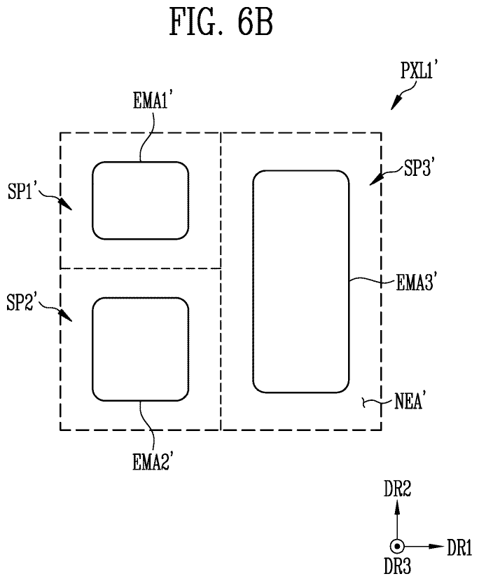

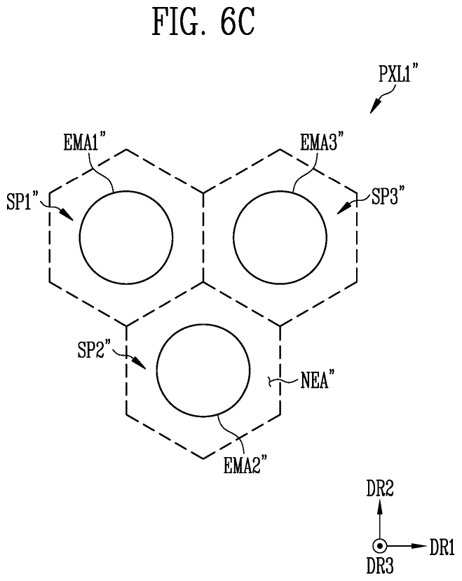

FIG. 6A illustrates a schematic top plan view of one of pixels of FIG. 5 according to one or more embodiments. For a clear and concise description in FIG. 6A, the first pixel PXL1 among the first and second pixels PXL1 and PXL2 of FIG. 5 is schematically illustrated. The remaining pixels may be configured similarly to the first pixel PXL1.

Referring to FIG. 5 and FIG. 6A, the first pixel PXL1 may include a first sub-pixel SP1, a second sub-pixel SP2, and a third sub-pixel SP3 arranged in the first direction DR1.

The first sub-pixel SP1 may include a first light-emitting area EMA1, and a non-light-emitting area NEA around the first light-emitting area EMA1. The second sub-pixel SP2 may include a second light-emitting area EMA2, and a non-light-emitting area NEA around the second light-emitting area EMA2. The third sub-pixel SP3 may include a third light-emitting area EMA3, and a non-light-emitting area NEA around the third light-emitting area EMA3.

The first light-emitting area EMA1 may be an area in which light is emitted from a portion of the light-emitting structure (see “EMS” in FIG. 5) corresponding to the first sub-pixel SP1. The second light-emitting area EMA2 may be an area in which light is emitted from a portion of the light-emitting structure EMS corresponding to the second sub-pixel SP2. The third light-emitting area EMA3 may be an area in which light is emitted from a portion of the light-emitting structure EMS corresponding to the third sub-pixel SP3. As described with reference to FIG. 5, each light-emitting area may be understood as the opening OP of the pixel-defining layer corresponding to each of the first to third sub-pixels SP1 to SP3.

FIG. 6B illustrates a schematic top plan view of one of pixels of FIG. 5 according to one or more other embodiments.

Referring to FIG. 6B, a first pixel PXL1′ may include a first sub-pixel SP1′, a second sub-pixel SP2′, and a third sub-pixel SP3′.

The first sub-pixel SP1′ may include a first light-emitting area EMA1′, and a non-light-emitting area NEA′ around the first light-emitting area EMA1′. The second sub-pixel SP2′ may include a second light-emitting area EMA2′, and a non-light-emitting area NEA′ around the second light-emitting area EMA2′. The third sub-pixel SP3′ may include a third light-emitting area EMA3′, and a non-light-emitting area NEA′ around the third light-emitting area EMA3′.

The first to third sub-pixels SP1′ to SP3′ may have quadrangular shapes when viewed in the third direction DR3.

The first sub-pixel SP1′ and the second sub-pixel SP2′ may be arranged in the second direction DR2 (e.g., with respect to each other). The third sub-pixel SP3′ may be located in the first direction DR1 with respect to each of the first and second sub-pixels SP1′ and SP2′.

The second sub-pixel SP2′ may have a larger area than the first sub-pixel SP1′, and the third sub-pixel SP3′ may have a larger area than the second sub-pixel SP2′. Accordingly, the second light-emitting area EMA2′ may have a larger area than the first light-emitting area EMA1′, and the third light-emitting area EMA3′ may have a larger area than the second light-emitting area EMA2′. However, embodiments are not limited thereto. For example, the first and second sub-pixels SP1′ and SP2′ may have substantially the same area, and the third sub-pixel SP3′ may have a larger area than each of the first and second sub-pixels SP1′ and SP2′. As such, the areas of the first to third sub-pixels SP1′ to SP3′ may be variously changed depending on embodiments.

FIG. 6C illustrates a schematic top plan view of one of pixels of FIG. 5 according to one or more other embodiments.

Referring to FIG. 6C, the first sub-pixel SP1″ may include a first light-emitting area EMA1″, and a non-light-emitting area NEA″ around the first light-emitting area EMA1″. The second sub-pixel SP2″ may include a second light-emitting area EMA2″, and a non-light-emitting area NEA″ around the second light-emitting area EMA2″. The third sub-pixel SP3″ may include a third light-emitting area EMA3″, and a non-light-emitting area NEA″ around the third light-emitting area EMA3″.

The first to third sub-pixels SP1″ to SP3″ may have polygonal shapes when viewed in the third direction DR3. For example, the shapes of the first to third sub-pixels SP1″ to SP3″ may have hexagonal shapes as shown in FIG. 6C.

The first to third light-emitting areas EMA1″ to EMA3″ may have circular shapes when viewed in the third direction DR3. However, embodiments are not limited thereto. For example, each of the first to third light-emitting areas EMA1″ to EMA3″ may have a polygonal shape.

The first and third sub-pixels SP1″ and SP3″ may be located in the first direction DR1 (e.g., with respect to each other). The second sub-pixel SP2″ may be located in a direction (or a diagonal direction) inclined by an acute angle with respect to the second direction DR2 with respect to the first sub-pixel SP1″.

The arrangement of the sub-pixels shown in FIG. 6A, FIG. 6B, and FIG. 6C is illustrative as merely an example, and the embodiments are not limited thereto. Each pixel may include two or more sub-pixels, the sub-pixels may be variously located, each of the sub-pixels may have various shapes, and each of its light-emitting areas may also have various shapes.

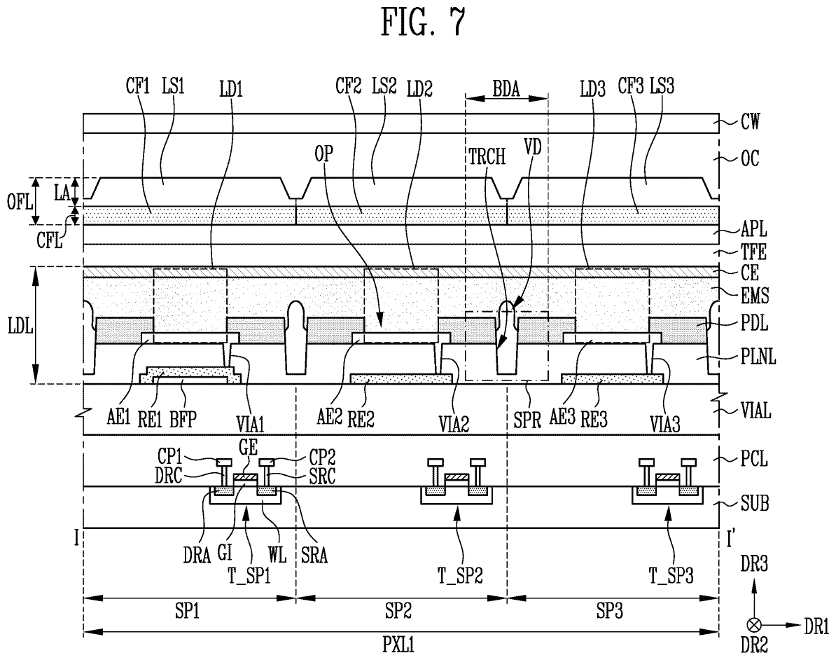

FIG. 7 illustrates a schematic cross-sectional view of one or more embodiments of a pixel taken along the line I-I′ of FIG. 6A.

Referring to FIG. 6A and FIG. 7, the first pixel PXL1 may include the first sub-pixel SP1, the second sub-pixel SP2, and the third sub-pixel SP3.

Each of the first to third sub-pixels SP1 to SP3 may include a substrate SUB and a pixel circuit layer PCL located on the substrate SUB.

The substrate SUB may include a silicon wafer substrate formed using a semiconductor process. For example, the substrate SUB may include silicon, germanium, and/or silicon-germanium.

The pixel circuit layer PCL may be located on the substrate SUB. The substrate SUB and the pixel circuit layer PCL may include circuit elements for each of the first to third sub-pixels SP1 to SP3. For example, the substrate SUB and the pixel circuit layer PCL may include a transistor T_SP1 of the first sub-pixel SP1, a transistor T_SP2 of the second sub-pixel SP2, and a transistor T_SP3 of the third sub-pixel SP3. The transistor T_SP1 of the first sub-pixel SP1 may be one of the transistors included in the sub-pixel circuit of the first sub-pixel SP1, the transistor T_SP2 of the second sub-pixel SP2 may be one of the transistors included in the sub-pixel circuit of the second sub-pixel SP2, and the transistor T_SP3 of the third sub-pixel SP3 may be one of the transistors included in the sub-pixel circuit of the third sub-pixel SP3. In FIG. 7, for clear and concise description, one of the transistors of each sub-pixel is shown and the remaining circuit elements are omitted.

The transistor T_SP1 of the first sub-pixel SP1 may include a source area SRA, a drain area DRA, and a gate electrode GE.

The source area SRA and the drain area DRA may be located within the substrate SUB. A well WL is located in the substrate SUB through an ion injection process, and the source area SRA and the drain area DRA may be spaced apart from each other within the well WL. The area between the source area SRA and the drain area DRA within the well WL may be defined as a channel area.

The gate electrode GE overlaps the channel area between the source area SRA and the drain area DRA, and may be located on the pixel circuit layer PCL. The gate electrode GE may be separated from the well WL or the channel area by an insulating material, such as a gate-insulating layer Gl. The gate electrode GE may include a conductive material.

A plurality of layers included in the pixel circuit layer PCL may include insulating layers and conductive patterns located between the insulating layers. The conductive patterns may include a first conductive pattern CP1 and a second conductive pattern CP2. The first conductive pattern CP1 may be electrically connected to the drain area DRA through a drain connection portion DRC penetrating one or more insulating layers. The second conductive pattern CP2 may be electrically connected to the source area SRA through a source connection portion SRC penetrating one or more insulating layers.

As the gate electrode GE and the first and second conductive patterns CP1 and CP2 are electrically connected to other circuit elements and/or wires, the transistor T_SP1 of the first sub-pixel SP1 may be provided as one of transistors configuring the sub-pixel circuit of the first sub-pixel SP1.

Each of the transistor T_SP2 of the second sub-pixel SP2 and the transistor T_SP3 of the third sub-pixel SP3 may be configured to be substantially the same as the transistor T_SP1 of the first sub-pixel SP1.

As described above, the substrate SUB and the pixel circuit layer PCL may include circuit elements for each of the first to third sub-pixels SP1 to SP3.

A via layer VIAL may be located on the pixel circuit layer PCL. The via layer VIAL covers the pixel circuit layer PCL, and may have an overall flat (or uniform) surface. The via layer VIAL may include at least one of a silicon oxide (SiOₓ), a silicon nitride (SiNₓ), or a silicon carbon nitride (SiCN), but embodiments are not limited thereto.

The light-emitting element layer LDL may be located on the via layer VIAL. The light-emitting element layer LDL may include first to third reflective electrodes RE1 to RE3, a planarization layer PLNL, first to third anode electrodes AE1 to AE3, a pixel-defining layer PDL, a light-emitting structure EMS, and a cathode electrode CE.

The first to third reflective electrodes RE1 to RE3 may be located in the first to third sub-pixels SP1 to SP3 on the via layer VIAL, respectively. For example, the first reflective electrode RE1 may be located on the via layer VIAL of the first sub-pixel SP1, the second reflective electrode RE2 may be located on the via layer VIAL of the second sub-pixel SP2, and the third reflective electrode RE3 may be located on the via layer VIAL of the third sub-pixel SP3. Each of the first to third reflective electrodes RE1 to RE3 may contact a circuit element located on the pixel circuit layer PCL through a via penetrating the via layer VIAL.

The first to third reflective electrodes RE1 to RE3 may function as full mirrors that reflect light emitted from the light-emitting structure EMS toward the display surface (or the cover window CW). The first to third reflective electrodes RE1 to RE3 may include metallic materials suitable for reflecting light. For example, the first to third reflective electrodes RE1 to RE3 may include at least one of aluminum, silver, magnesium, platinum, palladium, gold, nickel, neodymium, iridium, chromium, or titanium, or may include at least one of alloys of two or more materials selected therefrom. However, the materials of the first to third reflective electrodes RE1 to RE3 are not limited to the above-described embodiments.

The first reflective electrode RE1, the second reflective electrode RE2, and the third reflective electrode RE3 may have the same thickness. For example, the thickness of each of the first reflective electrode RE1, the second reflective electrode RE2, and the third reflective electrode RE3 may be about 700 Å to about 1000 Å, or may be about 850 Å, but embodiments are not limited thereto.

In some embodiments, a connection electrode may be located below each of the first to third reflective electrodes RE1 to RE3. The connection electrode may be provided to improve the electrical connection characteristics between the corresponding reflective electrode and the circuit element of the pixel circuit layer PCL. The connection electrode may be configured of a multi-layered layer. For example, the multi-layered layer may include a structure in which titanium/titanium nitride (or titanium nitride)/tantalum nitride (or tantalum nitride) is stacked, but is not limited thereto. In some embodiments, the corresponding reflective electrode may be located between the layers configuring the connection electrode.

In embodiments, a buffer pattern BFP may be located below at least one of the first to third reflective electrodes RE1 to RE3. For example, the buffer pattern BFP may be located between the first reflective electrode RE1 and the via layer VIAL. The buffer pattern BFP may include an inorganic material, such as a silicon carbon nitride, but is not limited thereto. By arranging the buffer pattern BFP, the height of the corresponding reflective electrode in the third direction DR3 may be adjusted. For example, the buffer pattern BFP may adjust the height of the first reflective electrode RE1, between the first reflective electrode RE1 and the via layer VIAL. The first reflective electrode RE1 may cover an upper surface and both side surfaces (or both end portions) of the buffer pattern BFP to entirely cover the buffer pattern BFP. One area of the first reflective electrode RE1 may extend to an upper surface of the via layer VIAL contacting both side surfaces of the buffer pattern BFP.

In the second sub-pixel SP2, the buffer pattern BFP described above may be omitted between the second reflective electrode RE2 and the via layer VIAL, and the second reflective electrode RE2 may be directly located on the via layer VIAL. In addition, in the third sub-pixel SP3, the buffer pattern BFP described above may be omitted between the third reflective electrode RE3 and the via layer VIAL, and the third reflective electrode RE3 may be directly located on the via layer VIAL.

The first to third reflective electrodes RE1 to RE3 may function as full mirrors, and the cathode electrode CE may function as a half mirror. Light emitted from the light-emitting structure EMS may be amplified at least partially by reciprocating between the reflective electrode and the cathode electrode CE, and the amplified light may be outputted through the cathode electrode CE. As such, the distance between each reflective electrode and the cathode electrode CE may be understood as the resonance distance for the light emitted from the light-emitting layer of the corresponding light-emitting structure EMS.

The first sub-pixel SP1 may have a shorter resonance distance than other sub-pixels (for example, the second and third sub-pixels SP2 and SP3) due to the buffer pattern BFP. The resonance distance adjusted in this way may allow light in a corresponding wavelength range (for example, red color) to be effectively and efficiently amplified. Accordingly, the first sub-pixel SP1 may effectively and efficiently output light in the corresponding wavelength range.

In FIG. 7, the buffer pattern BFP is shown to be provided in the first sub-pixel SP1, and not in the second and third sub-pixels SP2 and SP3, but the embodiments are not limited thereto. In some embodiments, the buffer pattern may be also provided in at least one of the second or third sub-pixels SP2 or SP3, so that the resonance distance of at least one of the second or third sub-pixels SP2 or SP3 may be adjusted. For example, in case that the first sub-pixel SP1 is a red sub-pixel, the second sub-pixel SP2 is a green sub-pixel, and the third sub-pixel SP3 is a blue sub-pixel, a distance between the first reflective electrode RE1 and the cathode electrode CE may be shorter than that between the second reflective electrode RE2 and the cathode electrode CE, and a distance between the second reflective electrode RE2 and the cathode electrode CE may be shorter than that between the third reflective electrode RE3 and the cathode electrode CE.

The thickness of the buffer pattern BFP (or the thickness in the third direction DR3) may be about 400 Å to about 600 Å, but embodiments are not limited thereto.

The planarization layer PLNL may be provided to planarize steps between the first to third reflective electrodes RE1 to RE3. The planarization layer PLNL may be located on the via layer VIAL and the first to third reflective electrodes RE1 to RE3. The planarization layer PLNL may entirely cover the first to third reflective electrodes RE1 to RE3 and the via layer VIAL, and may have a flat surface. The planarization layer PLNL may include an insulating material. For example, the planarization layer PLNL may include an inorganic material, such as a silicon oxide (SiOₓ) and a silicon nitride (SiNₓ), but embodiments are not limited thereto. In some embodiments, the planarization layer PLNL may be omitted.

In embodiments, the planarization layer PLNL may include a via that exposes one area of the reflective electrode. For example, the planarization layer PLNL may include a first via VIA1 exposing one area of the first reflective electrode RE1, a second via VIA2 exposing one area of the second reflective electrode RE2, and a third via VIA3 exposing one area of the third reflective electrode RE3.

The first anode electrode AE1, the second anode electrode AE2, and the third anode electrode AE3 may be located on the planarization layer PLNL. For example, the first anode electrode AE1 may be located on the planarization layer PLNL to overlap the first reflective electrode RE1, the second anode electrode AE2 may be located on the planarization layer PLNL to overlap the second reflective electrode RE2, and the third anode electrode AE3 may be located on the planarization layer PLNL to overlap the third reflective electrode RE3.

The first to third anode electrodes AE1 to AE3 may have shapes similar to the first to third light-emitting areas EMA1 to EMA3 of FIG. 6A when viewed in the third direction DR3. For example, the first anode electrode AE1 may have a shape similar to that of the first light-emitting area EMA1 when viewed in the third direction DR3, the second anode electrode AE2 may have a shape similar to that of the second light-emitting area EMA2 when viewed in the third direction DR3, and the third anode electrode AE3 may have a shape similar to that of the third light-emitting area EMA3 when viewed in the third direction DR3, but embodiments are not limited thereto.

Each of the first to third anode electrodes AE1 to AE3 may be electrically connected to a corresponding reflective electrode. For example, the first anode electrode AE1 may be electrically connected to the first reflective electrode RE1 through the first via VIA1 penetrating the planarization layer PLNL. The second anode electrode AE2 may be electrically connected to the second reflective electrode RE2 through the second via VIA2 penetrating the planarization layer PLNL. The third anode electrode AE3 may be electrically connected to the third reflective electrode RE3 through the third via VIA3 penetrating the planarization layer PLNL.

In embodiments, the first anode electrode AE1 may be located within the first via VIA1 to directly contact, and to be connected to, the first reflective electrode RE1 exposed by the first via VIA1. The second anode electrode AE2 may be located within the second via VIA2 to directly contact, and to be connected to, the second reflective electrode RE2 exposed by the second via VIA2. The third anode electrode AE3 may be located within the third via VIA3 to directly contact, and to be connected to, the third reflective electrode RE3 exposed by the third via VIA3.

The first to third anode electrodes AE1 to AE3 may include at least one of a transparent conductive materials, such as an indium tin oxide (ITO), an indium zinc oxide (IZO), a zinc oxide (ZnOₓ), an indium gallium zinc oxide (IGZO), or an indium tin zinc oxide (ITZO). However, the materials of the first to third anode electrodes AE1 to AE3 are not limited thereto. For example, the first to third anode electrodes AE1 to AE3 may include a titanium nitride.

In embodiments, the first to third anode electrodes AE1 to AE3 may have the same thickness. For example, the thickness of each of the first anode electrode AE1, the second anode electrode AE2, and the third anode electrode AE3 may be about 700 Å to about 1000 Å, but is not limited thereto.

Insulating layers for adjusting a height of one or more of the first to third anode electrodes AE1 to AE3 may be further provided. The insulating layers may be located between one or more of the first to third anode electrodes AE1 to AE3 and the corresponding electrodes. In this case, the planarization layer PLNL and/or the buffer pattern BFP may be omitted.

The pixel-defining layer PDL may be located on some of the first to third anode electrodes AE1 to AE3 and the planarization layer PLNL. The pixel-defining layer PDL may include an opening OP exposing a portion of each of the first to third anode electrodes AE1 to AE3. The opening OP of the pixel-defining layer PDL may define the light-emitting area of each of the first to third sub-pixels SP1 to SP3. The pixel-defining layer PDL may be located in the non-light-emitting area (see “NEA” in FIG. 6A), and may define the first light-emitting area EMA1, the second light-emitting area EMA2, and the third light-emitting area EMA3 described with reference to FIG. 6A.

In embodiments, the pixel-defining layer PDL may include a plurality of inorganic insulating layers. Each of the plurality of inorganic insulating layers may include at least one of a silicon oxide or a silicon nitride. For example, the pixel-defining layer PDL may include first to third inorganic insulating layers sequentially stacked, and each of the first to third inorganic insulating layers may include a silicon nitride, a silicon oxide, and a silicon oxynitride. However, the material of the pixel-defining layer PDL is not limited to the above-described embodiments.

A separator SPR may be provided in the boundary area BDA between the sub-pixels adjacent to each other. The separator SPR may cause a discontinuity to be formed within the light-emitting structure EMS in the boundary area BDA. For example, the light-emitting structure EMS may be disconnected or bent in the boundary area BDA by the separator SPR.

The separator SPR may be provided in or on the pixel-defining layer PDL. The pixel-defining layer PDL may include one or more trenches TRCH as the separator SPR in the boundary area BDA. In embodiments, one or more trenches TRCH may be formed to penetrate the pixel-defining layer PDL, and may partially penetrate the planarization layer PLNL. In other embodiments, one or more trenches TRCH may penetrate the pixel-defining layer PDL and the planarization layer PLNL, and may partially penetrate the via layer VIAL. In still other embodiments, one or more trenches TRCH may at least partially penetrate the planarization layer PLNL and/or the via layer VIAL, and a portion of the pixel-defining layer PDL may be located within one or more trenches TRCH. In still other embodiments, one or more trenches TRCH may be formed to partially penetrate the pixel-defining layer PDL.

One or more trenches TRCH may be provided in the boundary area BDA. For example, one trench TRCH may be located in the boundary area BDA between the second sub-pixel SP2 and the third sub-pixel SP3. However, it is not limited thereto, and two or more trenches separated from each other may be located in the boundary area BDA.

Due to the trench TRCH, discontinuous portions, such as one or more voids VD in the boundary area BDA may be formed in the light-emitting structure EMS. Some of the plurality of layers stacked within the light-emitting structure EMA (or components included within the light-emitting structure EMA) may be disconnected or bent by one or more voids VD. For example, at least one charge generation layer included in the light-emitting structure EMS may be disconnected in one or more voids VD. As described above, due to one or more trenches TRCH, the light-emitting structure EMS included in the first to third sub-pixels SP1 to SP3 may be at least partially separated (e.g., partially removed).

One or more trenches TRCH may include, or may be defined by, at least a portion of the pixel-defining layer PDL penetrated and a portion of the planarization layer PLNL recessed. One or more trenches TRCH may be formed by an etching method, for example, a dry etching method, but is not limited thereto. In other words, the one or more trenches TRCH are formed by removing at least a portion of the pixel-defining layer PDL and the planarization layer PLNL from the upper surface of the pixel-defining layer PDL toward the lower surface of the planarization layer PLNL.

In FIG. 7, it is shown that one void VD is formed in the light-emitting structure EMS in the boundary area BDA only as an example, and embodiments are not limited thereto. For example, a valley of a concave shape may be formed in the light-emitting structure EMS in the boundary area BDA. Depending on the shape of the one or more trenches TRCH, the shape of the discontinuous portions formed in the light-emitting structure EMS, for example, the shape of the one or more voids VD may be variously changed.

In embodiments, the light-emitting structure EMS may be formed through processes, such as vacuum deposition or inkjet printing. In this case, the same material as some of the components included in the light-emitting structure EMS may be located on the bottom surfaces of the one or more trenches TRCH adjacent to the via layer VIAL.

The separator SPR may be variously deformed to allow the light-emitting structure EMS to be able to have a discontinuity in the boundary area BDA. In embodiments, additional inorganic insulating patterns (or inorganic insulating layers) may be provided on the pixel-defining layer PDL in the boundary area BDA without one or more trenches TRCH. A width of the uppermost inorganic insulating pattern among the additionally stacked inorganic insulating patterns may be greater than a width of the inorganic insulating pattern located directly below the uppermost inorganic insulating pattern. For example, in the boundary area BDA, the first to third inorganic insulating patterns are sequentially stacked from the pixel-defining layer PDL, and the uppermost third inorganic insulating pattern may have a larger width than the second inorganic insulating pattern. In this case, the pixel-defining layer PDL may have a cross-section of a “T” or “I” shape in the boundary area BDA. Depending on the shape of the pixel-defining layer PDL, a plurality of layers included in the light-emitting structure EMS may be at least partially disconnected or bent in the boundary area BDA.

The light-emitting structure EMS may be located on the anode electrodes (“AE” in FIG. 5) exposed by the opening OP of the pixel-defining layer PDL. The light-emitting structure EMS may fill the opening OP of the pixel-defining layer PDL, and may be located entirely across the first to third sub-pixels SP1 to SP3. As described above, the light-emitting structure EMS may be at least partially disconnected or bent in the boundary area BDA by the separator SPR. Accordingly, when the display panel (see “110” in FIG. 5) operates, the current leaking from each of the first to third sub-pixels SP1 to SP3 to the neighboring sub-pixel through the layers included in the light-emitting structure EMS may decrease. Accordingly, the first, second, and third light-emitting elements LD1, LD2, and LD3 may operate with relatively high reliability.

The cathode electrode CE may be located on the light-emitting structure EMS. The cathode electrode CE may be provided commonly for the first to third sub-pixels SP1 to SP3. The cathode electrode CE may function as a half mirror that partially transmits and that partially reflects light emitted from the light-emitting structure EMS.

The first anode electrode AE1 (or a first electrode), the portion of the light-emitting structure EMS overlapping the first anode electrode AE1, and the portion of the cathode electrode CE (or a second electrode) overlapping the first anode electrode AE1 may configure the first light-emitting element LD1. The second anode electrode AE2 (or a first electrode), the portion of the light-emitting structure EMS overlapping the second anode electrode AE2, and the portion of the cathode electrode CE (or a second electrode) overlapping the second anode electrode AE2 may configure the second light-emitting element LD2. The third anode electrode AE3 (or a first electrode), the portion of the light-emitting structure EMS overlapping the third anode electrode AE3, and the portion of the cathode electrode CE (or a second electrode) overlapping the third anode electrode AE3 may configure the third light-emitting element LD3.

The encapsulation layer TFE may be located on the cathode electrode CE. The encapsulation layer TFE may reduce or prevent permeation of oxygen and/or moisture into the light-emitting element layer LDL.

The optical functional layer OFL may be located on the encapsulation layer TFE. In embodiments, the optical functional layer OFL may be attached to the encapsulation layer TFE through an adhesive layer APL. For example, the optical functional layer OFL may be separately manufactured to be attached to the encapsulation layer TFE through the adhesive layer APL. The adhesive layer APL may further perform a function of protecting the lower layers including the encapsulation layer TFE.

The optical functional layer OFL may include a color filter layer CFL and a lens array LA.

The color filter layer CFL may include first to third color filters CF1 to CF3 respectively corresponding to the first to third sub-pixels SP1 to SP3. For example, the color filter layer CFL may include the first color filter CF1 corresponding to the first sub-pixel SP1, the second color filter CF2 corresponding to the second sub-pixel SP2, and the third color filter CF3 corresponding to the third sub-pixel SP3. The first to third color filters CF1 to CF3 may pass light in different wavelength ranges. For example, the first color filter CF1 may pass red color light, the second color filter CF2 may pass green color light, and the third color filter CF3 may pass blue color light. In this case, the first sub-pixel SP1 may be a red sub-pixel, the second sub-pixel SP2 may be a green sub-pixel, and the third sub-pixel SP3 may be a blue sub-pixel.

In embodiments, the first to third color filters CF1 to CF3 may partially overlap in the boundary area BDA. In other embodiments, the first to third color filters CF1 to CF3 may be spaced apart from each other, and a black matrix may be provided between the spaced first to third color filters CF1 to CF3.

The lens array LA may be located on the color filter layer CFL. The lens array LA may include first to third lenses LS1 to LS3 respectively corresponding to the first to third sub-pixels SP1 to SP3. For example, the lens array LA may include the first lens LS1 corresponding to the first sub-pixel SP1, the second lens LS2 corresponding to the second sub-pixel SP2, and the third lens LS3 corresponding to the third sub-pixel SP3. The first to third lenses LS1 to LS3 may improve light output efficiency by outputting the light emitted from the first to third light-emitting elements LD1 to LD3, respectively, along an intended path.

An overcoat layer OC may be located on the optical function layer OFL, and a cover window CW may be located on the overcoat layer OC.

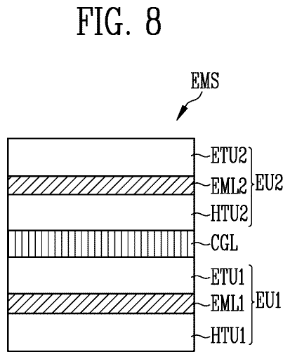

FIG. 8 illustrates a schematic cross-sectional view of the light-emitting structure EMS included in one of first to third light-emitting elements of FIG. 7 according to one or more embodiments.

Referring to FIG. 7 and FIG. 8, the light-emitting structure EMS may have a tandem structure in which a first light-emitting portion EU1 and a second light-emitting portion EU2 are stacked. The light-emitting structure EMS' may be configured to be substantially the same in each of the first to third light-emitting elements LD1 to LD3 of FIG. 7, but embodiments are not limited thereto.

Each of the first and second light-emitting portions EU1 and EU2 may include at least one light-emitting layer that generates light according to a current applied thereto. The first light-emitting portion EU1 may include a first light-emitting layer EML1, a first electron transport portion ETU1, and a first hole transport portion HTU1. The second light-emitting portion EU2 may include a second light-emitting layer EML2, a second electron transport portion ETU2, and a second hole transport portion HTU2. The second light-emitting layer EML2 may be located between the second electron transport portion ETU2 and the second hole transport portion HTU2.

Each of the first and second hole transport portions HTU1 and HTU2 may include at least one of a hole injection layer or a hole transport layer, and may further include a hole buffer layer, an electron-blocking layer, or the like as needed. The first and second hole transport portions HTU1 and HTU2 may have the same configuration or different configurations.

Each of the first and second electron transport portions ETU1 and ETU2 may include at least one of an electron injection layer or an electron transport layer, and may further include an electron buffer layer and a hole-blocking layer as needed. The first and second electron transport portions ETU1 and ETU2 may have the same configuration or different configurations.

An intermediate layer (or a connection layer), which may be provided in the form of the charge generation layer CGL, may be located between the first light-emitting portion EU1 and the second light-emitting portion EU2 to connect the first light-emitting portion EU1 and the second light-emitting portion EU2 to each other. Hereinafter, the charge generation layer CGL will be referred to as an intermediate layer. In embodiments, the intermediate layer CGL may have a stacked structure of a p dopant layer and an n dopant layer. For example, the p dopant layer may include a p-type dopant, such as HAT-CN, TCNQ, and NDP-9, and the n dopant layer may include an alkali metal, an alkaline earth metal, a lanthanide-based metal, or a combination thereof. However, the structure (or material) of the intermediate layer CGL is not limited to the above-described embodiments. In embodiments, the intermediate layer CGL may include a material having a relatively higher charge conductivity (or charge mobility) than the first and second light-emitting portions EU1 and EU2, thereby having conductivity.

In embodiments, the first light-emitting layer EML1 and the second light-emitting layer EML2 may generate light of different colors. The light emitted from each of the first light-emitting layer EML1 and the second light-emitting layer EML2 may be mixed to be recognized as white light. For example, the first emission layer EML1 may generate blue color light, and the second emission layer EML2 may include a structure in which a first sub-light-emitting layer configured to generate red color light and a second sub-light-emitting layer configured to generate green color light are stacked. In this case, a functional layer configured to perform a function of transporting holes and/or reducing or preventing transport of electrons may be further located between the first and second sub-light-emitting layers.

In other embodiments, the first light-emitting layer EML1 and the second light-emitting layer EML2 may generate light of the same color.

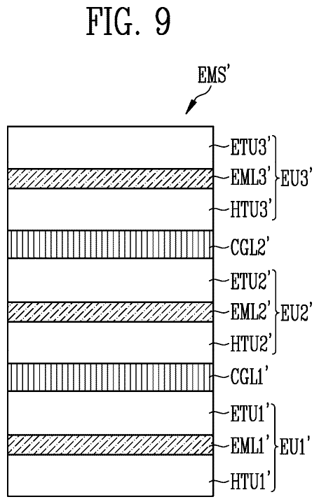

FIG. 9 illustrates a schematic cross-sectional view of a light-emitting structure EMS' included in one of first to third light-emitting elements of FIG. 7 according to one or more other embodiments.

Referring to FIG. 7 and FIG. 9, the light-emitting structure EMS' may have a tandem structure in which first, second, and third light-emitting portions EU1′, EU2′, and EU3′ are stacked. The light-emitting structure EMS' may be configured to be substantially the same in each of the first to third light-emitting elements LD1 to LD3 of FIG. 7.

Each of the first to third light-emitting portions EU1′ to EU3′ may include a light-emitting layer that generates light according to a current applied thereto. The first light-emitting portion EU1′ may include a first light-emitting layer EML1′, a first electron transport portion ETU1′, and a first hole transport portion HTU1′. The first light-emitting layer EML1′ may be located between the first electron transport portion ETU1′ and the first hole transport portion HTU1′. The second light-emitting portion EU2′ may include a second light-emitting layer EML2′, a second electron transport portion ETU2′, and a second hole transport portion HTU2′. The second light-emitting layer EML2′ may be located between the second electron transport portion ETU2′ and the second hole transport portion HTU2′. The third light-emitting portion EU3′ may include a third light-emitting layer EML3′, a third electron transport portion ETU3′, and a third hole transport portion HTU3′. The third light-emitting layer EML3′ may be located between the third electron transport portion ETU3′ and the third hole transport portion HTU3′.

Each of the first to third hole transport portions HTU1′ to HTU3′ may include at least one of a hole injection layer or a hole transport layer, and may further include a hole buffer layer, an electron-blocking layer, or the like as needed. The first to third hole transport portions HTU1′ to HTU3′ may have the same configuration or different configurations.

Each of the first to third electron transport portions ETU1′ to ETU3′ may include at least one of an electron injection layer or an electron transport layer, and may further include an electron buffer layer and a hole-blocking layer as needed. The first to third electron transport portions ETU1′ to ETU3′ may have the same configuration or different configurations.

A first intermediate layer CGL1′ may be located between the first light-emitting portion EU1′ and the second light-emitting portion EU2′. A second intermediate layer CGL2′ may be located between the second light-emitting portion EU2′ and the third light-emitting portion EU3′. In embodiments, the first intermediate layer CGL1′ and the second intermediate layer CGL2′ include a material having relatively higher charge conductivity (or charge mobility) than those of the first light-emitting portion EU1′, the second light-emitting portion EU2′, and the third light-emitting portion EU3′, and thus may have conductivity.

In embodiments, the first to third light-emitting layers EML1′ to EML3′ may generate light of different colors. Light emitted from each of the first to third light-emitting layers EML1′ to EML3′ may be mixed to be viewed as white light. For example, the first light-emitting layer EML1′ may generate light of a blue color, the second light-emitting layer EML2′ may generate light of a green color, and the third light-emitting layer EML3′ may generate light of a red color.

In other embodiments, two or more of the first to third light-emitting layers EML1′ to EML3′ may generate light of the same color.

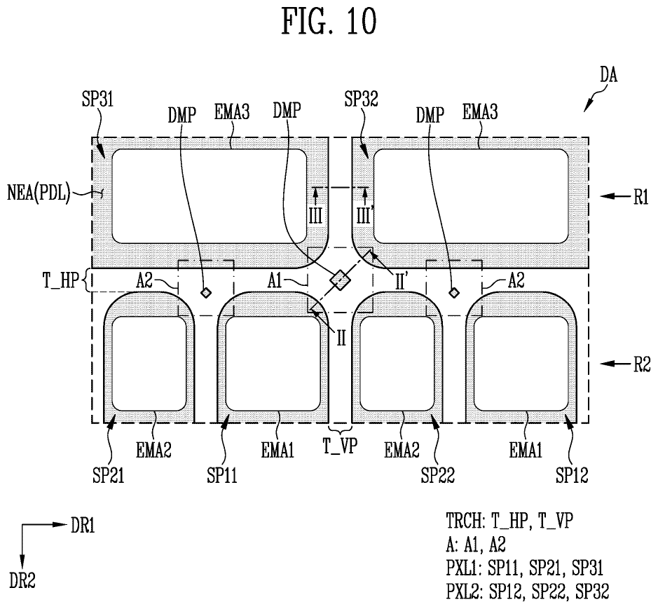

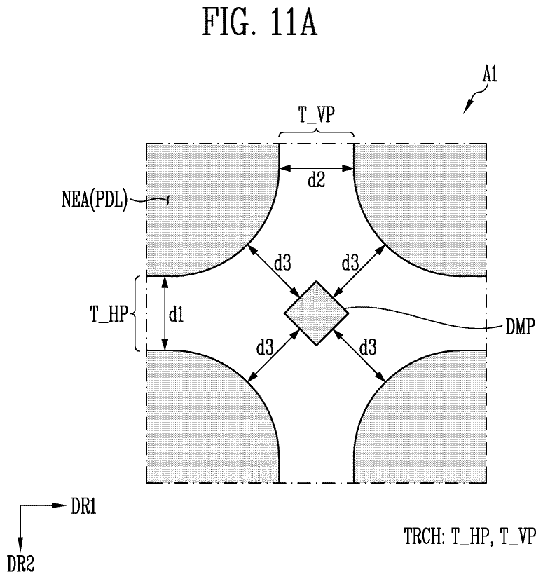

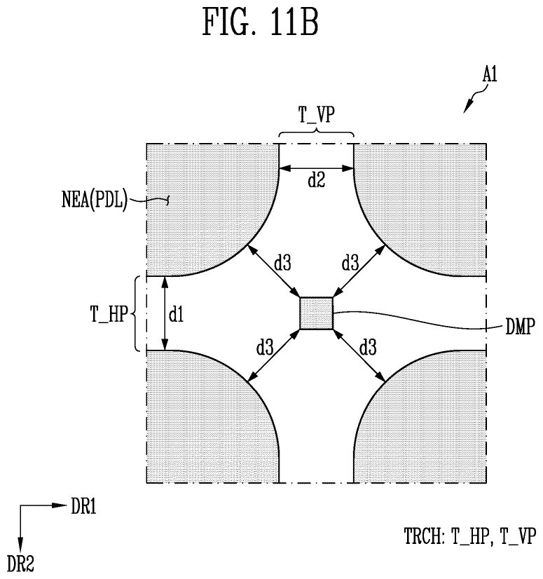

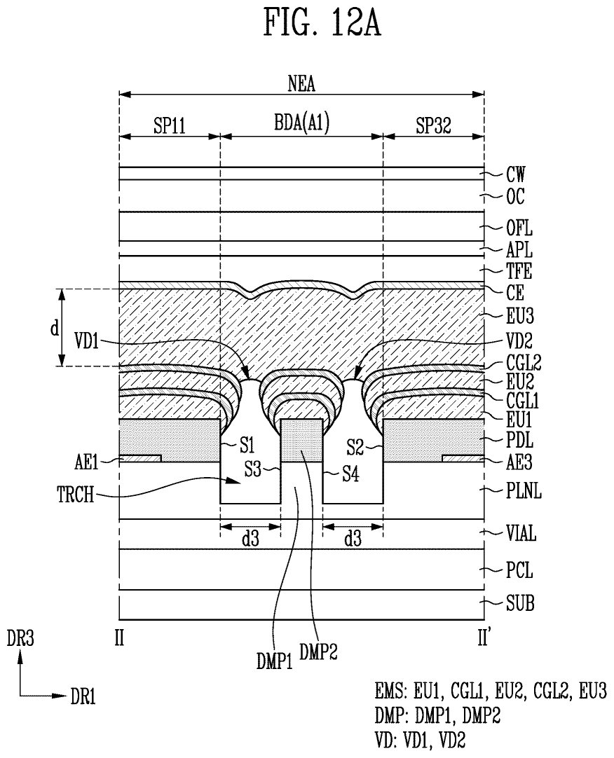

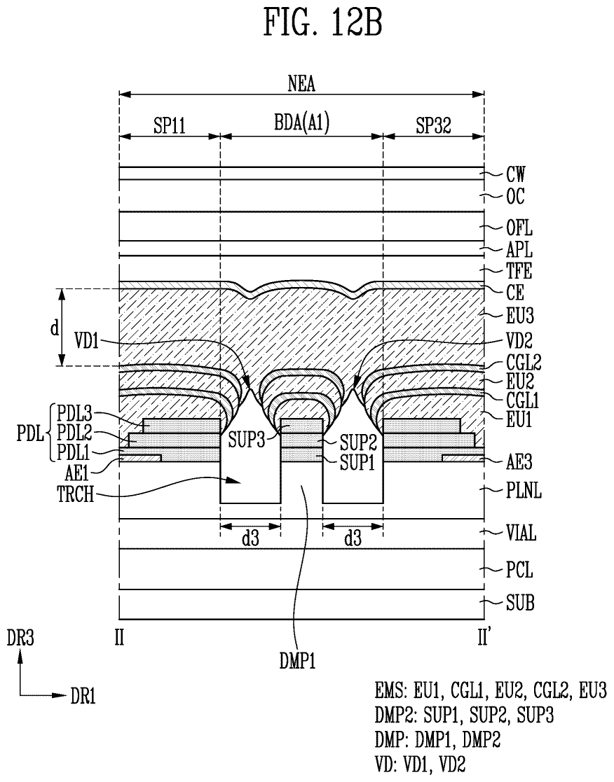

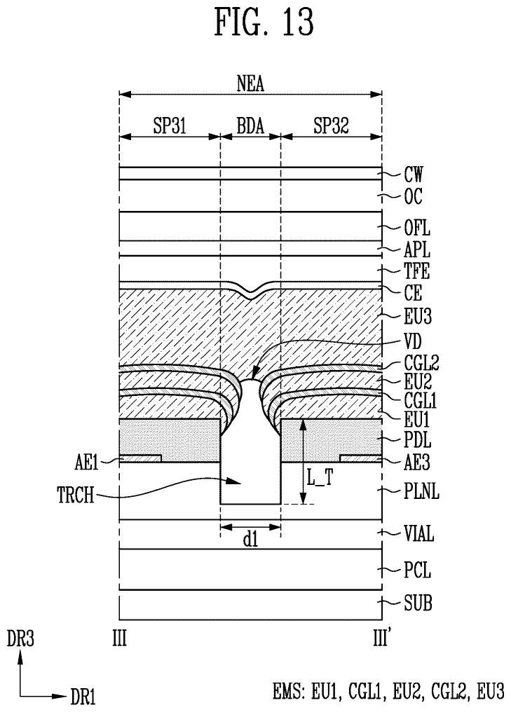

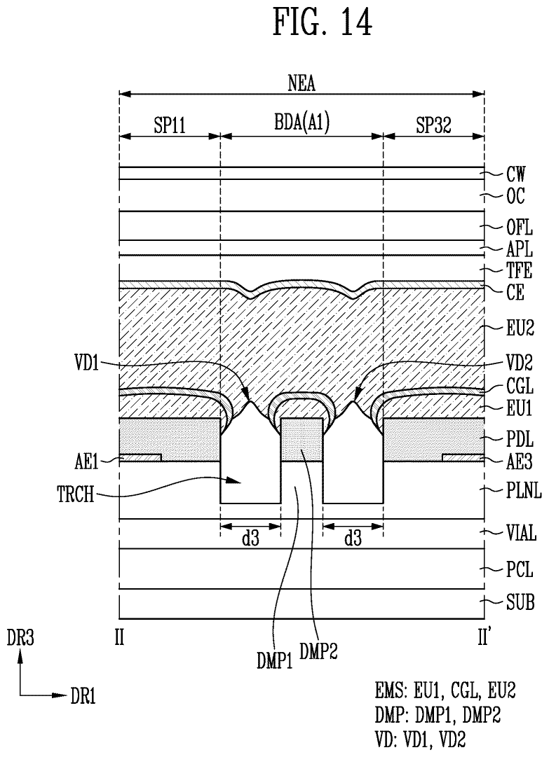

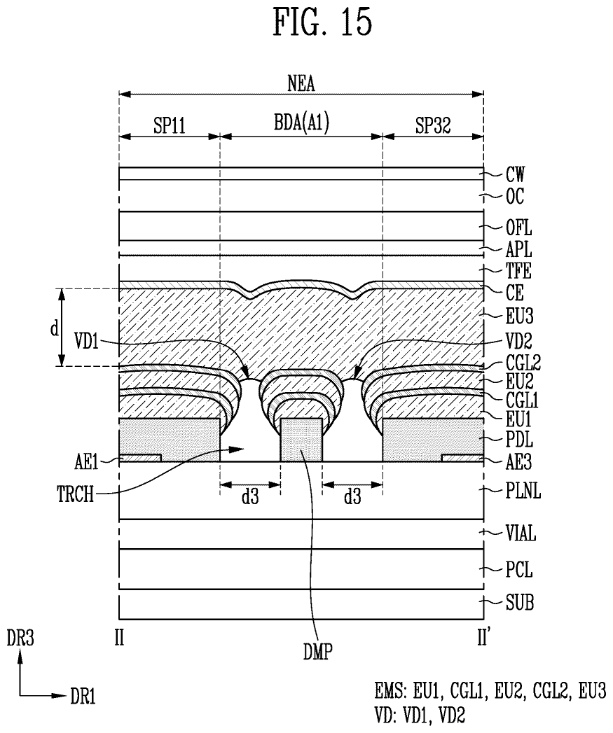

FIG. 10 illustrates a schematic top plan view of one portion of a display area DA of FIG. 4, FIG. 11A and FIG. 11B illustrate schematic enlarged top plan views of area A1 of FIG. 10, FIG. 12A and FIG. 12B illustrate a schematic cross-sectional view taken along the line II-II′ of FIG. 10, FIG. 13 illustrates a schematic cross-sectional view taken along the line III-III′ of FIG. 10, and FIG. 14 and FIG. 15 illustrate enlarged views of a portion of the display device of FIG. 7, and illustrate cross-sectional views taken along the line II-II′ of FIG. 10.

In FIG. 10 to FIG. 15, differences from the above-described embodiments will be mainly described to avoid duplicate descriptions.

Referring to FIG. 4 and FIG. 10 to FIG. 15, the display area DA may be divided into pixel rows R1 and R2. The pixel rows R1 and R2 may extend in the first direction DR1, and may be arranged in the second direction DR2.

A first pixel PXL1 and a second pixel PXL2 located adjacent to each other may be located in the display area DA. The first pixel PXL1 and the second pixel PXL2 may be arranged in the first direction DR1. The first pixel PXL1 may include an eleventh sub-pixel SP11 (or a first sub-pixel), a twenty-first sub-pixel SP21 (or a second sub-pixel), and a thirty-first sub-pixel SP31 (or a third sub-pixel). The second pixel PXL2 may include a twelfth sub-pixel SP12 (or a first sub-pixel), a twenty-second sub-pixel SP22 (or a second sub-pixel), and a thirty-second sub-pixel SP32 (or a third sub-pixel).

The thirty-first sub-pixel SP31 and the thirty-second sub-pixel SP32 may be located in the first pixel row R1. The eleventh sub-pixel SP11, the twenty-first sub-pixel SP21, the twelfth sub-pixel SP12, and the twenty-second sub-pixel SP22 may be located in the second pixel row R2, but are not limited thereto. In some embodiments, the eleventh sub-pixel SP11, the twenty-first sub-pixel SP21, the twelfth sub-pixel SP12, and the twenty-second sub-pixel SP22 may be located in the first pixel row R1, and the thirty-first sub-pixel SP31 and the thirty-second sub-pixel SP32 may be located in the second pixel row R2.

Each of the eleventh sub-pixel SP11 and the twelfth sub-pixel SP12 may include a first light-emitting area EMA1. Each of the twenty-first sub-pixel SP21 and the twenty-second sub-pixel SP22 may include a second light-emitting area EMA2. Each of the thirty-first sub-pixel SP31 and the thirty-second sub-pixel SP32 may include a third light-emitting area EMA3. The non-light-emitting area NEA may be located around the first light-emitting area EMA1, the second light-emitting area EMA2, and the third light-emitting area EMA3 (e.g., in plan view). The pixel-defining layer PDL may be located in the non-light-emitting area NEA. The eleventh sub-pixel SP11 and the twelfth sub-pixel SP12 may emit light of a first color, the twenty-first sub-pixel SP21 and the twenty-second sub-pixel SP22 may emit light of a second color, and the thirty-first sub-pixel SP31 and the thirty-second sub-pixel SP32 may emit light of a third color. The light of the first color may be red light, the light of the second color may be green light, and the light of the third color may be blue light, but the present disclosure is not limited thereto.

The eleventh sub-pixel SP11, the twenty-first sub-pixel SP21, and the thirty-first sub-pixel SP31 may have quadrangular shapes including curved surfaces when viewed in a plan view. The twelfth sub-pixel SP12, the twenty-second sub-pixel SP22, and the thirty-second sub-pixel SP32 may have quadrangular shapes including curved surfaces when viewed in a plan view.

The twenty-first sub-pixel SP21 and the eleventh sub-pixel SP11 may be arranged in the first direction DR1. The thirty-first sub-pixel SP31 may be located in a direction opposite to the second direction DR2 with respect to each of the eleventh and twenty-first sub-pixels SP11 and SP21. The twenty-second sub-pixel SP22 and the twelfth sub-pixel SP12 may be arranged in the first direction DR1. The thirty-second sub-pixel SP32 may be located in a direction opposite to the second direction DR2 with respect to each of the twelfth and twenty-second sub-pixels SP12 and SP22.

The eleventh sub-pixel SP11 and the twelfth sub-pixel SP12 may have the same size, the twenty-first sub-pixel SP21 and the twenty-second sub-pixel SP22 may have the same size, and the thirty-first sub-pixel SP31 and the thirty-second sub-pixel SP32 may have the same size. The eleventh sub-pixel SP11 may have an area that is larger than the twenty-first sub-pixel SP21, and the thirty-first sub-pixel SP31 may have an area that is larger than the eleventh sub-pixel SP11. The twelfth sub-pixel SP12 may have an area that is larger than the twelfth sub-pixel SP22, and the thirty-second sub-pixel SP32 may have an area that is larger than the twelfth sub-pixel SP12. Accordingly, the first light-emitting area EMA1 may have a larger area than the second light-emitting area EMA2, and the third light-emitting area EMA3 may have a larger area than the first light-emitting area EMA1.

In embodiments, the trench TRCH may be located between adjacent sub-pixels. The trench TRCH may be located in the non-light-emitting area NEA between adjacent sub-pixels to surround the light-emitting area of the corresponding sub-pixel and its surroundings. For example, the trench TRCH may surround (e.g., in plan view) the first light-emitting area EMA1, the second light-emitting area EMA2, the third light-emitting area EMA3, and peripheries of respective light-emitting areas.

The trench TRCH may be a structure formed by recessing or penetrating a base layer (for example, the upper surface of the pixel-defining layer PDL) for the arrangement of the light-emitting structure EMS. In a plan view, the trench TRCH may be located between adjacent sub-pixels (or in a boundary area, e.g., see “BDA” in FIG. 7) along an edge of each of the eleventh sub-pixel SP11, the twelfth sub-pixel SP12, the twenty-first sub-pixel SP21, the twenty-second sub-pixel SP22, the thirty-first sub-pixel SP31, and the thirty-second sub-pixel SP32.

The trench TRCH may include a horizontal portion T_HP extending in the first direction DR1 and a vertical portion T_VP extending in the second direction DR2 crossing the first direction DR1. The horizontal portion T_HP and the vertical portion T_VP may be connected to each other. Accordingly, the trench TRCH may have a mesh shape.

The trench TRCH may include a crossing portion(s) (or intersection portion) A where the horizontal portion T_HP and the vertical portion T_VP cross each other (e.g., intersect each other). The crossing portion A may include a first crossing portion A1 and a second crossing portion A2.

The first crossing portion A1 may correspond to one area of the trench TRCH where one vertical portion T_VP extending in the second direction DR2 across both the first pixel row R1 and the second pixel row R2, and one horizontal portion T_HP located between the first pixel row R1 and the second pixel row R2 cross each other. The first crossing portion A1 may have a “+” shape when viewed in a plan view. The first crossing portion A1 may be understood as a crossroad intersection.

The second crossing portion A2 may correspond to one area of the trench TRCH where one vertical portion T_VP located between the twenty-first sub-pixel SP21 and the eleventh sub-pixel SP11, and one horizontal portion T_HP located between the first pixel row R1 and the second pixel row R2, cross each other. In addition, the second crossing portion A2 may correspond to one area of the trench TRCH where one vertical portion T_VP located between the twenty-second sub-pixel SP22 and the twelfth sub-pixel SP12, and one horizontal portion T_HP located between the first pixel row R1 and the second pixel row R2, cross each other. The second crossing portion A2 may have a “T” shape when viewed in a plan view. The second crossing portion A2 may be understood as a three-way crossing region, or three-way intersection.

In embodiments, a dummy pattern DMP may be located in the crossing portion A. The dummy pattern DMP may correspond to a separate structure located within the trench TRCH. When viewed in a plan view, the dummy pattern DMP may have a polygonal shape, such as a rhombus, but is not limited thereto. In some embodiments, as shown in FIG. 11B, the dummy pattern (DMP) may have a quadrangular shape, such as a square shape or a rectangular type when viewed in a plan view.

In FIG. 10, the dummy pattern DMP located in the first crossing portion A1, and the dummy pattern DMP located in the second crossing portion A2, are shown as having different respective areas, but are not limited thereto. In some embodiments, the dummy pattern DMP located in the first crossing portion A1 and the dummy pattern DMP located in the second crossing region A2 may have the same area.

The dummy pattern DMP may include the same material as the pixel-defining layer PDL. The dummy pattern DMP may include a first dummy pattern DMP1 and a second dummy pattern DMP2. The first dummy pattern DMP1 may be formed by the same process as the planarization layer PLNL to be provided to the same layer as the planarization layer PLNL, and may include the same material as the planarization layer PLNL. The second dummy pattern DMP2 may be located on the first dummy pattern DMP1, may be formed by the same process as the pixel-defining layer PDL to be provided to the same layer as the pixel-defining layer PDL, and may include the same material as the pixel-defining layer PDL. The upper surface of the second dummy pattern DMP2 (or the surface of the dummy pattern DMP) may be located on the same line as (e.g., may be coplanar with) the upper surface (or the surface) of the pixel-defining layer PDL. As shown in FIG. 12A, the trench TRCH may include a portion that penetrates the pixel-defining layer PDL and a portion in which the planarization layer PLNL is recessed, or may be defined (or formed) by them.

The first dummy pattern DMP1 and the second dummy pattern DMP2 may be an inorganic layer containing an inorganic material.

As shown in FIG. 12B, the pixel-defining layer PDL may include a first inorganic insulating layer PDL1 (or a first inorganic insulating pattern), a second inorganic insulating layer PDL2 (or a second inorganic insulating pattern), and a third inorganic insulating layer PDL3 (or a third inorganic insulating pattern), which are sequentially stacked along the third direction DR3, but is not limited thereto. In some embodiments, the pixel-defining layer PDL may further include additional inorganic insulating layers in addition to the inorganic insulating layers described above.

The first inorganic insulating layer PDL1 and the third inorganic insulating layer PDL3 may include a silicon nitride, and the second inorganic insulating layer PDL2 may include a silicon oxide. However, the materials of the first to third inorganic insulating layers PDL1 to PDL3 are not limited to the above-described embodiments. The pixel-defining layer PDL including the first, second, and third inorganic insulating layers PDL1, PDL2, and PDL3 may have a step-shaped cross-section in an area adjacent to the opening (see “OP” in FIG. 7), but is not limited thereto. In some embodiments, the pixel-defining layer PDL may not have a step-shaped cross section in an area adjacent to the opening OP.

In some embodiments, the second dummy pattern DMP2 may include a first sub-pattern SUP1, a second sub-pattern SUP2, and a third sub-pattern SUP3, which are sequentially stacked along the third direction DR3. The first sub-pattern SUP1 may be formed through the same process as, may be located on the same layer as, and may include the same material as, the first inorganic insulating layer PDL1 of the pixel-defining layer PDL. The second sub-pattern SUP2 may be formed through the same process as, may be located on the same layer as, and may include the same material as, the second inorganic insulating layer PDL2 of the pixel-defining layer PDL. The third sub-pattern SUP3 may be formed through the same process as, may be located on the same layer as, and may include the same material as, the third inorganic insulating layer PDL3 of the pixel-defining layer PDL.

The horizontal portion T_HP of the trench TRCH may have a first width d1 in the second direction DR2, and the vertical portion T_VP of the trench TRCH may have a second width d2 in the first direction DR1. The first width d1 may mean an interval in the second direction DR2 between the pixel-defining layers PDL with the horizontal portion T_HP of the trench TRCH interposed therebetween, and the second width d2 may mean an interval in the first direction DR1 between the pixel-defining layers PDL with the vertical portion T_VP of the trench TRCH interposed therebetween. The first width d1 and the second width d2 may be the same as, or substantially similar to, each other. For example, the first width d1 and the second width d2 may be about 125 nm to about 135 nm, but are not limited thereto.

The horizontal portion T_HP of the trench TRCH and the vertical portion T_VP of the trench TRCH may have the same depth. For example, the horizontal portion T_HP of the trench TRCH and the vertical portion T_VP of the trench TRCH may have a depth L_T of about 4000 nm or more, but are not limited thereto.

The dummy pattern DMP may be spaced apart from the pixel-defining layer PDL. A shortest distance d3 between the dummy pattern DMP and the pixel-defining layer PDL in a diagonal direction of the first direction DR1 or the second direction DR2, in the first crossing portion A1 of the trench TRCH, may be similar to or the same as the first width d1 and/or the second width d2. For example, the shortest distance d3 between the dummy pattern DMP and the pixel-defining layer PDL in the first crossing portion A1 may be about 125 nm to about 135 nm, but is not limited thereto.

At least in the non-light-emitting area NEA, the light-emitting structure EMS may be located on the pixel-defining layer PDL and the dummy pattern DMP. The light-emitting structure EMS may include a first light-emitting portion EU1, a second light-emitting portion EU2, and a third light-emitting portion EU3. In embodiments, the light-emitting structure EMS may be formed by a vacuum deposition method, but is not limited thereto. The light-emitting structure EMS may further include a first intermediate layer CGL1 and a second intermediate layer CGL2. The first intermediate layer CGL1 (or the first charge generation layer) may be located between the first light-emitting portion EU1 and the second light-emitting portion EU2, and the second intermediate layer CGL2 (or the second charge generation layer) may be located between the second light-emitting portion EU2 and the third light-emitting portion EU3. In embodiments, each of the first, second, and third light-emitting portions EU1, EU2, and EU3 may include a light-emitting layer that generates light according to a current applied thereto. The first light-emitting portion EU1 may be the same as the first light-emitting portion EU1′ described with reference to FIG. 9, the second light-emitting portion EU2 may be the same as the second light-emitting portion EU2′ described with reference to FIG. 9, and the third light-emitting portion EU3 may be the same as the third light-emitting portion EU3′ described with reference to FIG. 9.

The first, second, and third light-emitting portions EU1, EU2, and EU3 may include a charge transport portion, a light-emitting layer, an electron transport portion, and a buffer layer, which may include a material with a relatively low charge conductivity (or charge mobility) compared to the first and second intermediate layers CGL1 and CGL2. In embodiments, the first, second, and third light-emitting portions EU1, EU2, and EU3 may include a material that has relatively higher insulating properties than the first and second intermediate layers CGL1 and CGL2. In this case, even if the first, second, and third light-emitting portions EU1, EU2, and EU3 are connected to each other on the trench TRCH, a current may not be transmitted to adjacent sub-pixels.

The first light-emitting portion EU1 may be located on the pixel-defining layer PDL and the second dummy pattern DMP2 in the non-light-emitting area NEA. In one or more embodiments, the first light-emitting portion EU1 may be located on the anode electrode of each sub-pixel exposed by the opening OP of the pixel-defining layer PDL in the light-emitting area. The first light-emitting portion EU1 may include a disconnection portion (or an open portion) separated within the trench TRCH located in the non-light-emitting area NEA, for example, the boundary area BDA between adjacent sub-pixels. The disconnection portion may be defined as a portion in which the first light-emitting portion EU1 is not continuously formed, but is disconnected within the trench TRCH. In this case, the first light-emitting portion EU1 of the adjacent sub-pixels may be separated from each other. For example, as shown in FIG. 12A, the first light-emitting portion EU1 of the eleventh sub-pixel SP11 may be separated from the first light-emitting portion EU1 of the thirty-second sub-pixel SP32. In addition, as shown in FIG. 13, the first light-emitting portion EU1 of the thirty-first sub-pixel SP31 may be separated from the first light-emitting portion EU1 of the thirty-second sub-pixel SP32. The first light-emitting portion EU1 of the adjacent sub-pixels may be spaced apart from the first light-emitting portion EU1 on the dummy pattern DMP. For example, as shown in FIG. 12A, the first light-emitting portion EU1 located on the pixel-defining layer PDL of the eleventh sub-pixel SP11 may be spaced apart from the first light-emitting portion EU1 on the dummy pattern DMP, and the first light-emitting portion EU1 located on the pixel-defining flayer PDL of the thirty-second sub-pixel SP32 may be spaced apart from the first light-emitting portion EU1 on the dummy pattern DMP.

The first intermediate layer CGL1 may be located on the first light-emitting portion EU1. The first intermediate layer CGL1 may include a disconnection portion separated within the trench TRCH. In this case, the first intermediate layer CGL1 of the adjacent sub-pixels may be separated from each other. For example, as shown in FIG. 12A, the first intermediate layer CGL1 of the eleventh sub-pixel SP11 may be separated from the first intermediate layer CGL1 of the thirty-second sub-pixel SP32. In addition, as shown in FIG. 13, the first intermediate layer CGL1 of the thirty-first sub-pixel SP31 may be separated from the first intermediate layer CGL1 of the thirty-second sub-pixel SP32. In some embodiments, an end portion of the first intermediate layer CGL1 may be covered by the second light-emitting portion EU2 located thereon within the trench TRCH. The first intermediate layer CGL1 of the adjacent sub-pixels may be spaced apart from the first intermediate layer CGL1 on the dummy pattern DMP. For example, as shown in FIG. 12A, the first intermediate layer CGL1 located on the pixel-defining layer PDL of the eleventh sub-pixel SP11 may be spaced apart from the first intermediate layer CGL1 on the dummy pattern DMP, and the first intermediate layer CGL1 located on the pixel-defining layer PDL of the thirty-second sub-pixel SP32 may be spaced apart from the first intermediate layer CGL1 on the dummy pattern DMP.

The second light-emitting portion EU2 may be located on the first intermediate layer CGL1. The second light-emitting portion EU2 may include a disconnection portion separated within the trench TRCH. In this case, the second light-emitting portion EU2 of the adjacent sub-pixels may be separated from each other. For example, as shown in FIG. 12A, the second light-emitting portion EU2 of the eleventh sub-pixel SP11 may be separated from the second light-emitting portion EU2 of the thirty-second sub-pixel SP32. In addition, as shown in FIG. 13, the second light-emitting portion EU2 of the thirty-first sub-pixel SP31 may be separated from the second light-emitting portion EU2 of the thirty-second sub-pixel SP32. The second light-emitting portion EU2 of the adjacent sub-pixels may be spaced apart from the second light-emitting portion EU2 on the dummy pattern DMP. For example, as shown in FIG. 12A, the second light-emitting portion EU2 located on the pixel-defining layer PDL of the eleventh sub-pixel SP11 may be spaced apart from the second light-emitting portion EU2 on the dummy pattern DMP, and the second light-emitting portion EU2 located on the pixel-defining layer PDL of the thirty-second sub-pixel SP32 may be spaced apart from the second light-emitting portion EU2 on the dummy pattern DMP.

The second intermediate layer CGL2 may be located on the second light-emitting portion EU2. The second intermediate layer CGL2 may include a disconnection portion separated within the trench TRCH. In this case, the second intermediate layer CGL2 of the adjacent sub-pixels may be separated from each other. For example, as shown in FIG. 12A, the second intermediate layer CGL2 of the eleventh sub-pixel SP11 may be separated from the second intermediate layer CGL2 of the thirty-second sub-pixel SP32. In addition, as shown in FIG. 13, the second intermediate layer CGL2 of the thirty-first sub-pixel SP31 may be separated from the second intermediate layer CGL2 of the thirty-second sub-pixel SP32. The second intermediate layer CGL2 of the adjacent sub-pixels may be spaced apart from the second intermediate layer CGL2 on the dummy pattern DMP. For example, as shown in FIG. 12A, the second intermediate layer CGL2 located on the pixel-defining layer PDL of the eleventh sub-pixel SP11 may be spaced apart from the second intermediate layer CGL2 on the dummy pattern DMP, and the second intermediate layer CGL2 located on the pixel-defining layer PDL of the thirty-second sub-pixel SP32 may be spaced apart from the second intermediate layer CGL2 on the dummy pattern DMP. In some embodiments, an end portion of the second intermediate layer CGL2 may be covered by the third light-emitting portion EU3 within the trench TRCH as shown in FIG. 12B.

The third light-emitting portion EU3 may be located on the second intermediate layer CGL2. The third light-emitting portion EU3 may be formed on the second intermediate layer CGL2 to have a relatively thick thickness d. The third light-emitting portion EU3 may also be formed on the second intermediate layer CGL2 on the dummy pattern DMP located within the trench TRCH. Accordingly, the third light-emitting portion EU3 may not be disconnected in the boundary area BDA between adjacent sub-pixels. For example, as shown in FIG. 12A, the third light-emitting portion EU3 of the eleventh sub-pixel SP11, the third light-emitting portion EU3 on the dummy pattern DMP, and the third light-emitting portion EU3 of the thirty-second sub-pixel SP32 may be connected to each other. In some embodiments, at least a portion of one third light-emitting portion EU3 of two adjacent sub-pixels and at least a portion of the third light-emitting portion EU3 of the remaining sub-pixel may be disconnected within the trench TRCH. For example, the lower surface of the third light-emitting portion EU3 (for example, one surface in contact with the second intermediate layer CGL2) of adjacent sub-pixels may be disconnected within the trench TRCH, and the upper surface facing the lower surface in the third direction DR3 (for example, one surface in contact with the cathode electrode CE) may be connected to each other. Accordingly, the third light-emitting portion EU3 may not be disconnected within the trench TRCH.

As described above, each of the first and second intermediate layers CGL1 and CGL2 may be disconnected at the upper portion of the trench TRCH. In this case, a current leaking from one sub-pixel to another adjacent sub-pixel is reduced or prevented through the first and second intermediate layers CGL1 and CGL2, and each sub-pixel may operate with high reliability. In case that each of the first and second intermediate layers CGL1 and CGL2 is disconnected at the upper portion of the trench TRCH, color mixing between adjacent sub-pixels is reduced or prevented, so that each sub-pixel may emit light of the intended color.

The cathode electrode CE may be located on the third light-emitting portion EU3. The cathode electrode CE may be made of a metal including a conductive material. The third light-emitting portion EU3 located below the cathode electrode CE may be formed to have a thickness d that is thicker than the first and second light-emitting portions EU1 and EU2. The thickness d of the third light-emitting portion EU3 may be an interval between the second intermediate layer CGL2 and the cathode electrode CE. In other words, the thickness d of the third light-emitting portion EU3 corresponding to the interval between the second intermediate layer CGL2 and the cathode electrode CE may be greater than the interval between the first intermediate layer CGL1 and the second intermediate layer CGL2 (or the thickness of the second light-emitting portion EU2). This may reduce or prevent defects that may occur due to a short circuit between the cathode electrode CE, which includes a material with high charge conductivity (or charge mobility), and the conductive second intermediate layer CGL2, and may reduce or prevent the likelihood of the cathode electrode CE being disconnected due to steps of the components (for example, the second intermediate layer CGL2, the second light-emitting portion EU2, the first intermediate layer CGL1, and the first light-emitting portion EU1) located below the cathode electrode CE. Due to the third light-emitting portion EU3 with the thick thickness d, the interval between the cathode electrode CE and the second intermediate layer CGL2 is further secured, thereby reducing or preventing defects in which the cathode electrode CE and the second intermediate layer CGL2 are short-circuited. In addition, due to the third light-emitting portion EU3, the steps of the components located therebelow are smoothened, so that the step coverage of the cathode electrode CE located on the third light-emitting portion EU3 is improved, thereby reducing or preventing the likelihood of the cathode electrode CE being disconnected on the trench TRCH.

A void VD may be formed within the trench TRCH. The void VD may be formed by some configurations of the disconnected light-emitting structure EMS and the remaining configurations of the connected light-emitting structure EMS, within the trench TRCH. The void VD may be surrounded by the light-emitting structure EMS within the trench TRCH. For example, in each of the horizontal portion T_HP and the vertical portion T_VP of the trench TRCH, the void VD may be surrounded by the first light-emitting portion EU1, the first intermediate layer CGL1, the second light-emitting portion EU2, the second intermediate layer CGL2, and the third light-emitting portion EU3.

In the crossing portion A of the trench TRCH, for example, in the first crossing portion A1, the void VD may include a first void VD1 and a second void VD2. The dummy pattern DMP may be located at the first crossing portion A1 of the trench TRCH, so that the light-emitting structure EMS may also be formed on the dummy pattern DMP. Accordingly, a portion of the light-emitting structure EMS on the pixel-defining layer PDL and a portion of the light-emitting structure EMS on the dummy pattern DMP may be connected to each other to form the void VD. For example, at the first crossing portion A1, the void VD may include the first void VD1 surrounded by a first sidewall S1 of the pixel-defining layer PDL, the light-emitting structure EMS located on the first sidewall S1 of the pixel-defining layer PDL, and a first sidewall S3 of the dummy pattern DMP. Also, the void VD may include the second void VD2 surrounded by a second sidewall S2 of the pixel-defining layer PDL (for example, a sidewall facing the first sidewall S1 of the pixel-defining layer PDL), the light-emitting structure EMS located on the second sidewall S2 of the pixel-defining layer PDL, and a second sidewall S4 of the dummy pattern DMP (for example, a sidewall facing the first sidewall S3 of the dummy pattern DMP). In other words, due to the dummy pattern DMP, at least two voids VD, for example, the first void VD1 and the second void VD2 may be formed in the first crossing portion A1 of the trench TRCH.

The first void VD1 and the second void VD2 may have substantially similar or identical cross-sectional shapes. In addition, the first void VD1 and the second void VD2 may have a cross-sectional shape substantially similar to or the same as the void VD included in each of the horizontal portion T_HP and the vertical portion T_VP of the trench TRCH.

In the above-described embodiments, the dummy pattern DMP located at the crossing portion A of the trench TRCH may be designed so that the shortest distance d3 to the pixel-defining layer PDL in a diagonal direction with respect to the first and second directions DR1 and DR2 is substantially similar to or the same as the first width d1 of the horizontal portion T_HP of the trench TRCH and the second width d2 of the vertical portion T_VP of the trench TRCH. In other words, the interval between the sidewalls of the pixel-defining layer PDL in the horizontal portion T_HP of the trench TRCH, the interval between the sidewalls of the pixel-defining layer PDL in the vertical portion T_VP of the trench TRCH, and the interval between the pixel-defining layer PDL and the dummy pattern DMP in the crossing portion A of the trench TRCH may be similar. Accordingly, the trench TRCH has a similar or identical dimension (e.g., CD or critical dimension, although the dimensions described herein are not necessarily “critical” according to the dictionary meaning of the word) regardless of the horizontal portion T_HP, the vertical portion T_VP, and the crossing portion A, thereby reducing or preventing defects due to CD deviation.

In addition, in the above-described embodiments, due to the dummy pattern DMP located at the crossing portion A of the trench TRCH, at least two voids VD, for example, the first void VD1 and the second void VD2, may be formed in the crossing portion A. Each of the first void VD1 and the second void VD2 may have a shape similar to or the same as the void VD formed in the horizontal portion T_HP of the trench TRCH and the void VD formed in the vertical portion T_VP of the trench TRCH. Accordingly, the voids VD with similar or identical shapes are formed in the horizontal portion T_HP, the vertical portion T_VP, and the crossing portion A of the trench TRCH, so that it is possible to reduced or prevent defects that may occur due to different void VD shapes.

In a conventional display device in which there is no dummy pattern DMP in the crossing portion A of the trench TRCH, the interval between the sidewalls of the pixel-defining layer PDL in the crossing portion A is greater than the interval between the sidewalls of the pixel-defining layer PDL in the horizontal portion T_HP of the trench TRCH, and greater than the interval between the sidewalls of the pixel-defining layer PDL in the vertical portion T_VP of the trench TRCH, and thus, the formation or control of the void VD in the crossing portion A may not be easy. As a result, a defect in the void VD may occur at the crossing portion A of the trench TRCH, thereby reducing the reliability of the display device (see “100” in FIG. 1).

Thus, in the above-described embodiments, the dummy pattern DMP located on the same layer and including the same material as the pixel-defining layer PDL is located at the crossing portion A of the trench TRCH to utilize the dummy pattern DMP as the pixel-defining layer PDL (or function as a separate structure instead of the pixel-defining layer PDL), so that the horizontal portion T_HP of the trench TRCH, the vertical portion T_VP of the trench TRCH, and the crossing portion A of the trench TRCH may have similar or identical dimension (e.g., CD).

In the above-described embodiments, the light-emitting structure EMS has been described as a tandem structure in which the first light-emitting portion EU1, the second light-emitting portion EU2, and the third light-emitting portion EU3 are stacked, but is not limited thereto. In some embodiments, the light-emitting structure EMS may be configured to have a tandem structure in which the first light-emitting portion EU1 and the second light-emitting portion EU2 are stacked as shown in FIG. 14. In this case, the light-emitting structure EMS may include the intermediate layer CGL located between the first light-emitting portion EU1 and the second light-emitting portion EU2, similar to the light-emitting structure EMS described with reference to FIG. 8.

Hereinafter, a light-emitting structure EMS including first and second light-emitting portions EU1 and EU2 and an intermediate layer CGL will be described with reference to FIG. 14.

Each of the first and second light-emitting portions EU1 and EU2 may include a light-emitting layer that generates light according to a current applied thereto. The first light-emitting portion EU1 may be the same as the first light-emitting portion EU1 described with reference to FIG. 8, and the second light-emitting portion EU2 may be the same as the second light-emitting portion EU2 described with reference to FIG. 8. Each of the first and second light-emitting portions EU1 and EU2 may include a charge transport portion, a light-emitting layer, an electron transport portion, a buffer layer, and the like including a material having a relatively lower charge conductivity than the intermediate layer CGL.

The first light-emitting portion EU1 may include a disconnection portion separated within the trench TRCH. In this case, the first light-emitting portion EU1 of the eleventh sub-pixel SP11 may be separated from the first light-emitting portion EU1 of the thirty-second sub-pixel SP32. The first light-emitting portion EU1 on the dummy pattern DMP may be spaced apart from the first light-emitting portion EU1 of the eleventh sub-pixel SP11 and from the first light-emitting portion EU1 of the thirty-second sub-pixel SP32. The first light-emitting portion EU1 on the dummy pattern DMP may be spaced apart from the first light-emitting portion EU1 on the pixel-defining layer PDL of the eleventh and thirty-second sub-pixels SP11 and SP32.

The intermediate layer CGL may be located on the first light-emitting portion EU1. The intermediate layer CGL may include a disconnection portion separated within the trench TRCH. In this case, the intermediate layer CGL of the eleventh sub-pixel SP11 may be separated from the intermediate layer CGL of the thirty-second sub-pixel SP32. The intermediate layer CGL on the dummy pattern DMP may be spaced apart from each of the intermediate layer CGL of the eleventh sub-pixel SP11 and the intermediate layer CGL of the thirty-second sub-pixel SP32. The intermediate layer CGL on the dummy pattern DMP may be spaced apart from the intermediate layer CGL on the pixel-defining layer PDL of the eleventh and thirty-second sub-pixels SP11 and SP32.

The second light-emitting portion EU2 may be located on the intermediate layer CGL. The second light-emitting portion EU2 may be formed on the intermediate layer CGL to be relatively thick. As the second light-emitting portion EU2 is also formed on the intermediate layer CGL on the dummy pattern DMP located within the trench TRCH, the second light-emitting portion EU2 may not be disconnected in the boundary area BDA between adjacent sub-pixels. In this case, the second light-emitting portion EU2 of the eleventh sub-pixel SP11, the second light-emitting portion EU2 on the dummy pattern DMP, and the second light-emitting portion EU2 of the thirty-second sub-pixel SP32 may be connected to each other. In some embodiments, at least a portion of one second light-emitting portion EU2 of two adjacent sub-pixels, and at least a portion of the second light-emitting portion EU2 of the remaining sub-pixel, may be disconnected within the trench TRCH.

In the above-described embodiments, it has been described that the dummy pattern DMP has the structure in which the first dummy pattern DMP1 located on the same layer as, and including the same material as, the planarization layer PLNL, is stacked with the second dummy pattern DMP2 located on the same layer as, and including the same material as, the pixel-defining layer PDL, but the present disclosure is not limited thereto. In some embodiments, as shown in FIG. 15, the dummy pattern DMP may be implemented as an insulating pattern located on the same layer as, and including the same material as, the pixel-defining layer PDL. In this case, the dummy pattern DMP may be located on the upper surface of the planarization layer PLNL in the crossing portion A of the trench TRCH.

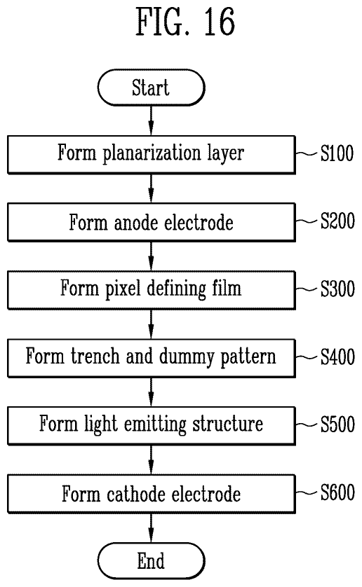

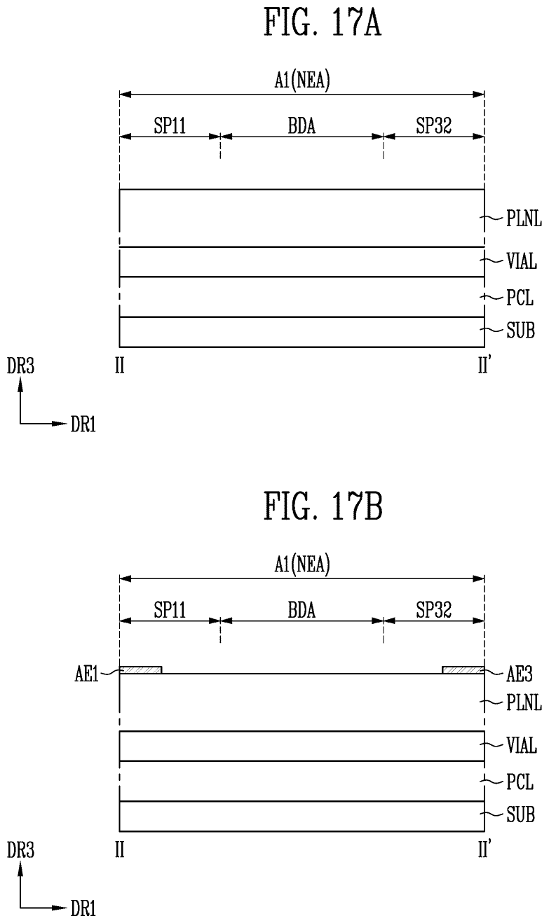

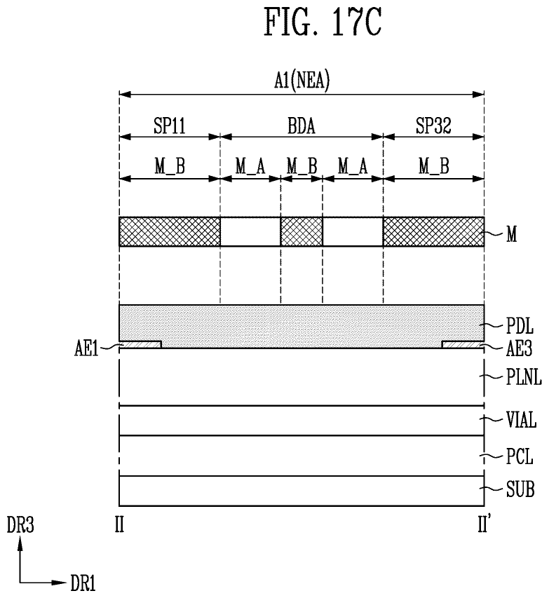

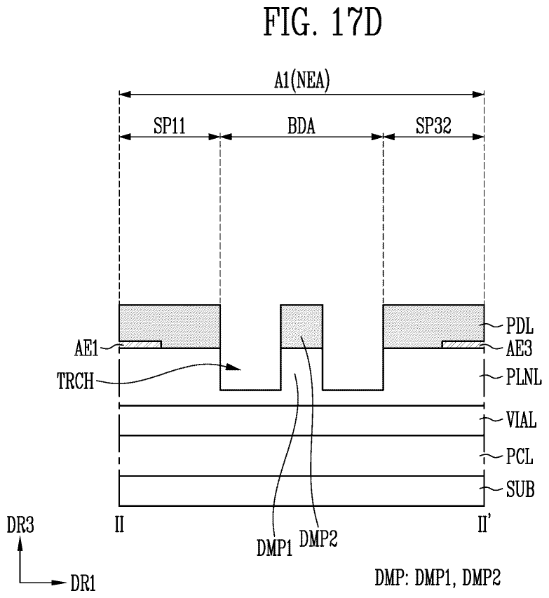

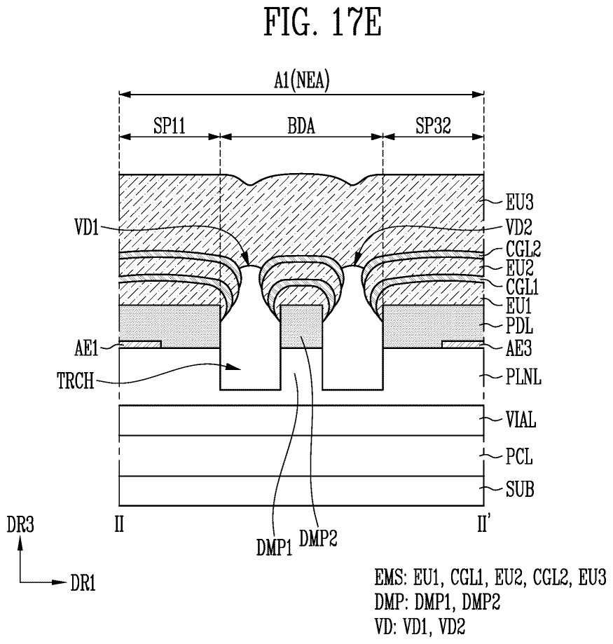

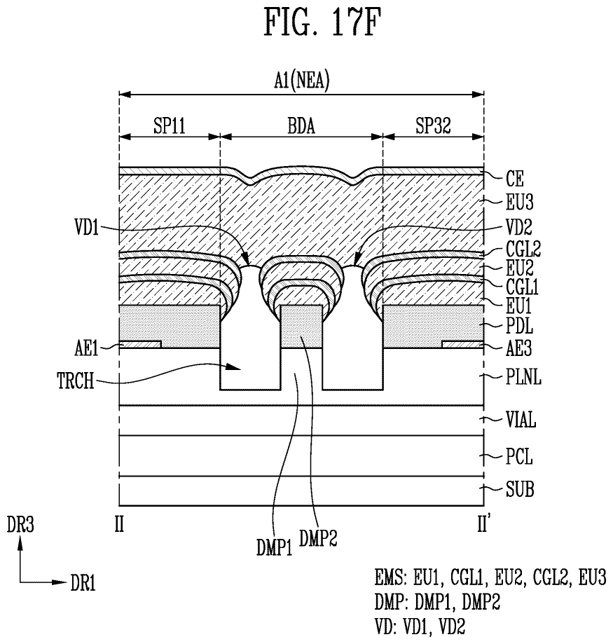

FIG. 16 illustrates a schematic flowchart of a manufacturing method of a display device according to one or more embodiments, and FIG. 17A to FIG. 17F illustrate schematic cross-sectional views of a manufacturing method of a display device according to one or more embodiments.

In FIG. 16 to FIG. 17F, for better comprehension and ease of description, duplicate descriptions of the above-described embodiments will be omitted.

Referring to FIG. 16 and FIG. 17A, the planarization layer PLNL is formed on the via layer VIAL (S100). For example, the planarization layer PLNL is formed on the via layer VIAL of adjacent sub-pixels.

Referring to FIG. 16 and FIG. 17B, the anode electrode is formed on the planarization layer PLNL (S200).

For example, the first anode electrode AE1 and the third anode electrode AE3, which are spaced apart from each other, may be formed on the planarization layer PLNL. The first anode electrode AE1 may be formed at a position corresponding to the first light-emitting area (see “EMA1” in FIG. 10) of the eleventh sub-pixel SP11, and the third anode electrode AE3 may be formed at a position corresponding to the third emission area (see “EMA3” in FIG. 10) of the thirty-second sub-pixel SP32.

Referring to FIG. 16 and FIG. 17C, the pixel-defining layer PDL is formed on the first and third anode electrodes AE1 and AE3 (S300).

For example, the pixel-defining layer PDL may be entirely formed on the first anode electrode AE1, the third anode electrode AE3, and the planarization layer PLNL. In this case, the pixel-defining layer PDL may include the opening (see “OP” in FIG. 7) exposing the anode electrode in the light-emitting area of each sub-pixel.

Subsequently, a mask M is located on the pixel-defining layer PDL. The mask M may include a first portion M_A and a second portion M_B. In this case, the first portion M_A may be a transmitting portion that completely transmits light, and the second portion M_B may be a blocking portion that completely blocks light, but are not limited thereto. The first portion M_A may correspond to an area of the pixel-defining layer PDL in which the trench (see “TRCH” in FIG. 12A) is to be formed, and the second portion M_B may correspond to an area of the pixel-defining layer PDL in which the trench TRCH is not formed and an area of the pixel-defining layer PDL in which the dummy pattern (see “DMP” in FIG. 12A) is to be formed.

Referring to FIG. 16 and FIG. 17D, a photolithography process using the above-described mask M is performed to form the trench TRCH, and the dummy pattern DMP is formed in the crossing portion (see “A” in FIG. 10) of the trench TRCH (S400).

For example, the pixel-defining layer PDL corresponding to the first portion M_A of the mask M in the boundary area BDA between adjacent sub-pixels and the eleventh sub-pixel SP11 and the thirty-second sub-pixel SP32 may be removed, and at least a portion of the planarization layer PLNL located below the pixel-defining layer PDL penetrates, so that the trench TRCH may be formed.

During the above-described photolithography process, the dummy pattern DMP configured in a form in which the first dummy pattern DMP1 and the second dummy pattern DMP2 are stacked may be formed in the crossing portion A of the trench TRCH. The second dummy pattern DMP2 may be the pixel-defining layer PDL that remains without being removed to correspond to the second portion M_B of the mask M in the photolithography process, and the first dummy pattern DMP1 may be the planarization layer PLNL located below the pixel-defining layer PDL.

In this case, the shortest distance (see “d3” in FIG. 11A) between the dummy pattern DMP and the pixel-defining layer PDL at the crossing portion A of the trench TRCH may be designed to be similar to, or equal to, the interval between the sidewalls of the pixel-defining layer PDL in the horizontal portion (see “T_HP” in FIG. 10) of the trench TRCH and the interval between the sidewalls of the pixel-defining layer PDL in the vertical portion (see “T_VP” in FIG. 10) of the trench TRCH.

Referring to FIG. 16 and FIG. 17E, the light-emitting structure EMS is formed on the pixel-defining layer PDL and the dummy pattern DMP (S500).

For example, the light-emitting structure EMS may include the first light-emitting portion EU1, the first intermediate layer CGL1, the second light-emitting portion EU2, the second intermediate layer CGL2, and the third light-emitting portion EU3, which are sequentially stacked in the third direction DR3. Each of the first light-emitting portion EU1, the first intermediate layer CGL1, the second light-emitting portion EU2, and the second intermediate layer CGL2 may have a disconnection portion within the trench TRCH. The third light-emitting portion EU3 may not be disconnected (e.g., may not be totally disconnected) within the trench TRCH.

Referring to FIG. 16 and FIG. 17F, the cathode electrode CE is formed on the light-emitting structure EMS (S600).

For example, the cathode electrode CE may be a common layer provided in common to adjacent sub-pixels, for example, the eleventh sub-pixel SP11 and the thirty-second sub-pixel SP32.

Thereafter, the remaining components shown in FIG. 12A, for example, the encapsulation layer TFE, the optical functional layer OFL, the overcoat layer OC, and the cover window CW, may be sequentially formed. Through this, the display device according to the one or more embodiments corresponding to FIG. 12A may be manufactured.

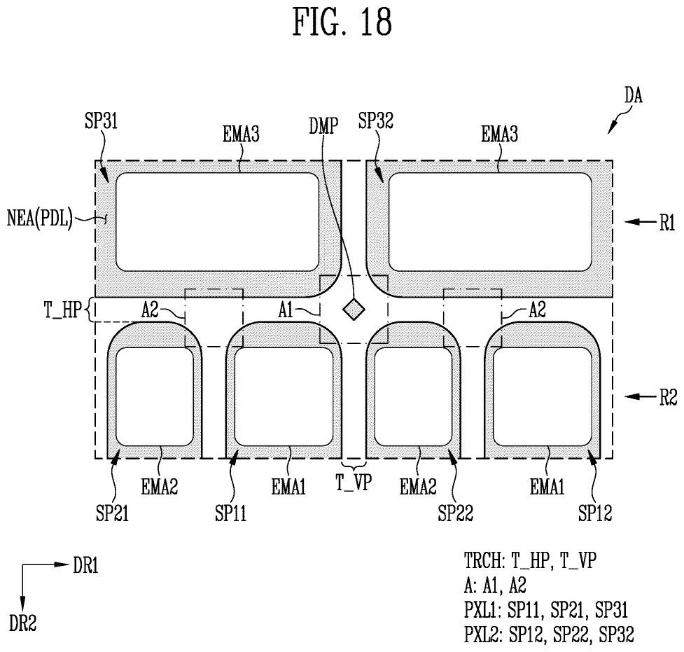

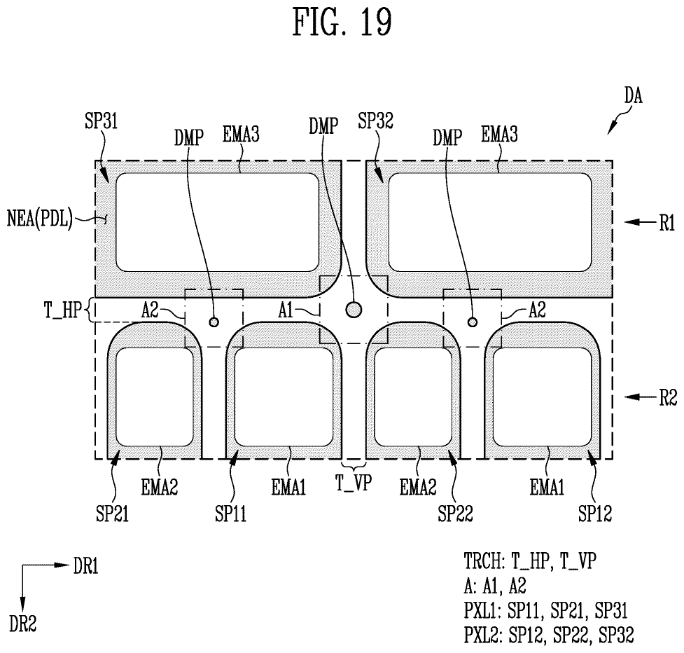

FIG. 18 and FIG. 19 illustrate schematic top plan views of one portion of the display area DA of the display device according to one or more embodiments.

In FIG. 18 and FIG. 19, differences from the above-described embodiments will be mainly described to avoid duplicate descriptions.

Referring to FIG. 18 and FIG. 19, the trench TRCH may be located between adjacent sub-pixels. The trench TRCH may include the horizontal portion T_HP extending in the first direction DR1, and the vertical portion T_VP extending in the second direction DR2 crossing the first direction DR1. The horizontal portion T_HP and the vertical portion T_VP may be connected to each other. Accordingly, the trench TRCH may have a mesh shape.

The trench TRCH may include the crossing portion A where the horizontal portion T_HP and the vertical portion T_VP cross each other. The crossing portion A may include the first crossing portion A1 and the second crossing portion A2. The first crossing portion A1 may have a “+” shape when viewed in a plan view, and may be understood as a crossroad intersection. The second crossing portion A2 may have a “T” shape when viewed in a plan view, and may be understood as a three-way crossing region.

As shown in FIG. 18, the dummy pattern DMP may be located in the first crossing portion A1, and the dummy pattern DMP may be omitted in the second crossing portion A2. The dummy pattern DMP may correspond to a separate structure located within the trench TRCH, and may be used as a separate structure corresponding to the pixel-defining layer PDL at the first crossing portion A1 of the trench TRCH. In other words, the dummy pattern DMP may be used as the pixel-defining layer PDL in the first crossing portion A1 of the trench TRCH.

The shortest distance between the dummy pattern DMP and the pixel-defining layer PDL in the first crossing portion A1 of the trench TRCH may be designed to be similar to or equal to the interval between the sidewalls of the pixel-defining layer PDL in the horizontal portion T_HP of the trench TRCH, and the interval between the sidewalls of the pixel-defining layer PDL in the vertical portion T_VP of the trench TRCH.

In some embodiments, as shown in FIG. 19, the dummy pattern DMP may be located in each of the first crossing portion A1 and the second crossing portion A2, and may have a circular shape when viewed in a plan view. The dummy pattern DMP located in the second crossing portion A2 may have a smaller area than the dummy pattern DMP located in the first crossing portion A1, but is not limited thereto. Because the crossing region area (e.g., intersection area) of the second crossing portion A2 between the vertical portion T_VP and the horizontal portion T_HP is smaller than that of the first crossing portion A1, the dummy pattern DMP located in the second crossing portion A2 may have a smaller area than the dummy pattern DMP located in the first crossing portion A1.

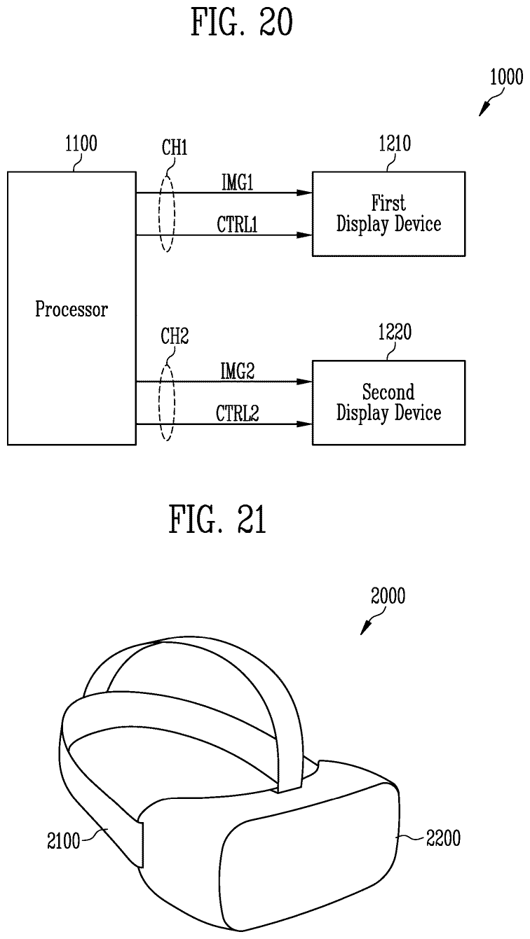

FIG. 20 illustrates a schematic block diagram of a display system 1000 according to one or more embodiments.

Referring to FIG. 20, the display system 1000 may include a processor 1100 and one or more display devices 1210 and 1220.

The processor 1100 may perform various tasks and calculations. In embodiments, the processor 1010 may include an application processor, a graphics processor, a microprocessor, a central processing unit (CPU), and the like. The processor 1100 may be connected to and step other constituent elements of the display system 1000 through a bus system.

In FIG. 20, the display system 1000 is shown to include the first and second display devices 1210 and 1220. The processor 1100 may be connected to the first display device 1210 through a first channel CH1 and to the second display device 1220 through a second channel CH2.

Through the first channel CH1, the processor 1100 may transmit first image data IMG1 and a first control signal CTRL1 to the first display device 1210. The first display device 1210 may display an image based on the first image data IMG1 and the first control signal CTRL1. The first display device 1210 may have the same configuration as the display device 100 described with reference to FIG. 1.

Through the second channel CH2, the processor 1100 may transmit second image data IMG2 and a second control signal CTRL2 to the second display device 1220. The second display device 1220 may display an image based on the second image data IMG2 and the second control signal CTRL2. The second display device 1220 may have the same configuration as the display device 100 described with reference to FIG. 1.

The display system 1000 may include a computing system providing image display functions, such as a portable computer, a mobile phone, a smart phone, a tablet personal computer (PC), a smart watch, a watch phone, a portable multimedia player (PMP), a navigation system, and a ultra mobile personal computer (UMPC). In addition, the display system 1000 may include at least one of a head-mounted display device (HMD), a virtual reality (VR) device, a mixed reality (MR) device, or an augmented reality (AR) device.

FIG. 21 illustrates a schematic perspective view of an application example of the display system of FIG. 20.

Referring to FIG. 21, the display system 1000 of FIG. 20 may be applied to a head-mounted display device 2000. The head-mounted display device 2000 may be a wearable electronic device that may be worn on the user's head.

The head-mounted display device 2000 may include a head-mounted band 2100 and a display device accommodation case 2200. The head-mounted band 2100 may be connected to the display device accommodation case 2200. The head-mounted band 2100 may be connected to the display device accommodation case 2200. The head-mounted band 2100 may include a horizontal band and/or a vertical band for fixing the head-mounted display device 2000 to the user's head. The horizontal band may be configured to surround the side portion of the user's head, and the vertical band may be configured to surround the upper portion of the user's head. However, the embodiments are not limited thereto. For example, the head-mounted band 2100 may be implemented in the form of a spectacle frame, a helmet, or the like.

The display device accommodation case 2200 may accommodate the first and second display devices 1210 and 1220 of FIG. 20. The display device accommodation case 2200 may further accommodate the processor 1100 of FIG. 20.

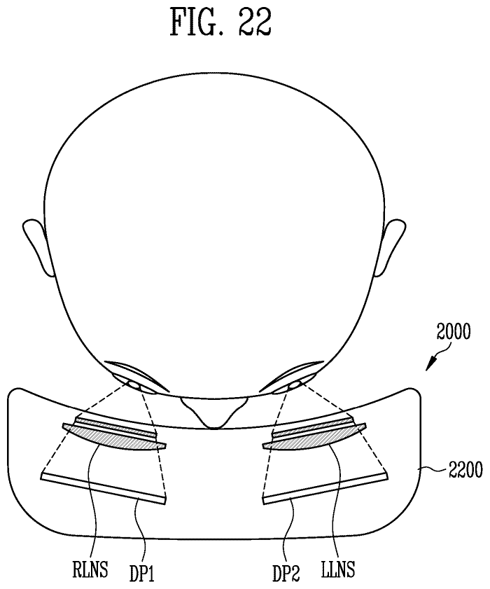

FIG. 22 schematically illustrates a user wearing a head-mounted display device of FIG. 21.

Referring to FIG. 22, a first display panel DP1 of the first display device (see “1210” in FIG. 20) and a second display panel DP2 of the second display device (see “1220” in FIG. 20) are located in the head-mounted display device 2000. The head-mounted display device 2000 may further include one or more lenses LLNS and RLNS.

In the display device accommodation case 2200, the right eye lens RLNS may be located between the first display panel DP1 and the right eye of the user, and the left eye lens LLNS may be located between the second display panel DP2 and the left eye of the user.

An image outputted from the first display panel DP1 may be shown to the right eye of the user through the right eye lens RLNS. The right eye lens RLNS may refract light from the first display panel DP1 to be directed to the right eye of the user. The right eye lens RLNS may perform an optical function to adjust the viewing distance between the first display panel DP1 and the right eye of the user.

An image outputted from the second display panel DP2 may be shown to the left of the user through the left eye lens LLNS. The left eye lens LLNS may refract light from the second display panel DP2 to be directed to the left eye of the user. The left eye lens LLNS may perform an optical function to adjust the viewing distance between the second display panel DP2 and the left eye of the user.

In embodiments, each of the right eye lens RLNS and the left eye lens LLNS may include an optical lens having a cross-section of a pancake shape. In the embodiments, each of the right eye lens RLNS and the left eye lens LLNS may include a multi-channel lens including sub-areas with different optical characteristics. In this case, each display panel outputs images corresponding to the sub-areas of the multi-channel lens, and the output images may pass through the sub-areas and be viewed by the user.

Although embodiments and applications have been described herein, other embodiments and modifications will be apparent from this description. Accordingly, the present disclosure is not limited to the embodiments, but rather to the broader scope of the presented claims and various modifications and equivalent arrangements.

What is claimed is:

1. A display device comprising:
a substrate;
sub-pixels respectively comprising a light-emitting area above the substrate;
a planarization layer above the substrate;
a pixel-defining layer above the planarization layer;
a trench defined by a recessed portion of the pixel-defining layer in a non-light-emitting area surrounding the light-emitting area, and comprising a horizontal portion extending in a first direction, and a vertical portion extending in a second direction crossing the first direction; and
a dummy pattern between adjacent ones of the sub-pixels in a crossing portion where the horizontal portion and the vertical portion cross.

2. The display device of claim 1, wherein the dummy pattern comprises a first dummy pattern, and a second dummy pattern above the first dummy pattern.

3. The display device of claim 2, wherein the first dummy pattern comprises a same material as the planarization layer, and the second dummy pattern comprises a same material as the pixel-defining layer.

4. The display device of claim 3, wherein the pixel-defining layer comprises a first inorganic insulating layer, a second inorganic insulating layer, and a third inorganic insulating layer sequentially stacked,
wherein the second dummy pattern comprises:
a first sub-pattern comprising a same material as, and at a same layer as, the first inorganic insulating layer;
a second sub-pattern comprising a same material as, and at a same layer as, the second inorganic insulating layer; and
a third sub-pattern comprising a same material as, and at a same layer as, the third inorganic insulating layer, the first, second, and third sub-patterns being sequentially stacked.

5. The display device of claim 1, wherein the horizontal portion has a first width in the second direction, and
wherein the vertical portion has a second width in the first direction that is substantially equal to the second width.

6. The display device of claim 5, wherein a shortest distance between the dummy pattern and a sidewall of the pixel-defining layer in a diagonal direction of the first and second directions in the crossing portion is substantially equal to the first width and the second width.

7. The display device of claim 1, wherein the dummy pattern has one of a quadrangular shape, a polygonal shape, or a circular shape in plan view.

8. The display device of claim 1, wherein the dummy pattern is above the planarization layer, and comprises a same material as the pixel-defining layer.

9. The display device of claim 1, further comprising:
an anode electrode of the sub-pixels above the planarization layer;
a light-emitting structure above the anode electrode in the light-emitting area, and above the pixel-defining layer and the dummy pattern in the non-light-emitting area; and
a cathode electrode above the light-emitting structure.

10. The display device of claim 9, wherein the light-emitting structure comprises:
a first light-emitting portion above the anode electrode and the pixel-defining layer, configured to emit light, and disconnected at the trench;
an intermediate layer above the first light-emitting portion, and disconnected at the trench; and
a second light-emitting portion above the intermediate layer, configured to emit light, and not disconnected at the trench.

11. The display device of claim 10, wherein the first light-emitting portion above the dummy pattern and the first light-emitting portion above the pixel-defining layer are spaced apart from each other,
wherein the intermediate layer above the dummy pattern and the intermediate layer above the pixel-defining layer are spaced apart from each other, and
wherein the second light-emitting portion above the dummy pattern and the second light-emitting portion above the pixel-defining layer are connected.

12. The display device of claim 11, wherein the crossing portion of the trench comprises a first void and a second void surrounded by the first light-emitting portion, the intermediate layer, the second light-emitting portion, and the dummy pattern.

13. The display device of claim 9, wherein the light-emitting structure comprises:
a first light-emitting portion above the anode electrode and the pixel-defining layer, and configured to emit light;
a first intermediate layer above the first light-emitting portion;
a second light-emitting portion above the first intermediate layer, and configured to emit light;
a second intermediate layer above the second light-emitting portion; and
a third light-emitting portion above the second intermediate layer, and configured to emit light, and
wherein the first light-emitting portion, the first intermediate layer, the second light-emitting portion, and the second intermediate layer are disconnected at the trench, and the third light-emitting portion is not disconnected at the trench.

14. The display device of claim 13, wherein the first light-emitting portion above the dummy pattern and the first light-emitting portion above the pixel-defining layer are spaced apart from each other,
wherein the first intermediate layer above the dummy pattern and the first intermediate layer above the pixel-defining layer are spaced apart from each other,
wherein the second light-emitting portion above the dummy pattern and the second light-emitting portion above the pixel-defining layer are spaced apart from each other,
wherein the second intermediate layer above the dummy pattern and the second intermediate layer above the pixel-defining layer are spaced apart from each other, and
wherein the third light-emitting portion above the dummy pattern and the third light-emitting portion above the pixel-defining layer of the sub-pixels are connected.

15. The display device of claim 14, wherein the crossing portion of the trench comprises a first void and a second void that are surrounded by the first light-emitting portion, the first intermediate layer, the second light-emitting portion, the second intermediate layer, the third light-emitting portion, and the dummy pattern.

16. The display device of claim 1, wherein the sub-pixels comprise a first sub-pixel configured to emit light of a first color, a second sub-pixel configured to emit light of a second color, and a third sub-pixel configured to emit light of a third color;
wherein the light-emitting area comprises a first light-emitting area forming the first sub-pixel, a second light-emitting area forming the second sub-pixel, and a third light-emitting area forming the third sub-pixel; and
wherein the trench surrounds the first light-emitting area, the second light-emitting area, and the third light-emitting area in plan view.

17. A wearable electronic device comprising:
a lens;
a display panel below the lens, and comprising:
a substrate
sub-pixels respectively comprising a light-emitting area above the substrate;
a planarization layer above the substrate;
a pixel-defining layer above the planarization layer;
a trench defined by a recessed portion of the pixel-defining layer in a non-light-emitting area surrounding the light-emitting area, and comprising a horizontal portion extending in a first direction, and a vertical portion extending in a second direction crossing the first direction; and
a dummy pattern between adjacent sub-pixels in the non-light-emitting area in a crossing portion where the horizontal portion and the vertical portion cross.

18. The wearable electronic device of claim 17, wherein the dummy pattern comprises a same material as the pixel-defining layer.

19. A method of manufacturing a display device comprising sub-pixels comprising a light-emitting area, the method comprising:
forming a planarization layer above a pixel circuit layer above a substrate;
forming an anode electrode above the planarization layer;
forming a pixel-defining layer above the planarization layer and the anode electrode;
arranging a mask above an upper portion of the pixel-defining layer;
performing a photolithography process to form a trench comprising a horizontal portion extending in a first direction, and a vertical portion extending in a second direction crossing the first direction, and a dummy pattern in a crossing portion where the horizontal portion and the vertical portion cross, by recessing at least a portion of the pixel-defining layer in a non-light-emitting area surrounding the light-emitting area;
forming a light-emitting structure above the pixel-defining layer, the trench, and the dummy pattern; and
forming a cathode electrode above the light-emitting structure.

20. The method of manufacturing the display device of claim 19, wherein the dummy pattern comprises a same material as the pixel-defining layer.
